(19) United States
(12) Patent Application Publication
(10) Pub. No.: US 2025/0392659 A1
(43) Pub. Date: Dec. 25, 2025

(54) DISPLAY DEVICE AND PORTABLE COMMUNICATION DEVICE INCLUDING THE SAME

(71) Applicant: Samsung Electronics Co., Ltd., Suwon-si (KR)

(72) Inventors: Sanguk KIM, Suwon-si (KR); Jongmin KIM, Suwon-si (KR); Joosung KIM, Suwon-si (KR); Hyoseok NA, Suwon-si (KR); Cheungwon RYU, Suwon-si (KR); Jonghyeok JEON, Suwon-si (KR); Wanjae JU, Suwon-si (KR)

(21) Appl. No.: 19/082,869

(22) Filed: Mar. 18, 2025

Related U.S. Application Data
(63) Continuation of application No. PCT/KR2025/003307, filed on Mar. 14, 2025.

(30) Foreign Application Priority Data
Jun. 24, 2024 (KR) 10-2024-0082092
Jul. 30, 2024 (KR) 10-2024-0100681

(51) Int. Cl. H04M 1/02

(52) U.S. Cl. CPC H04M 1/0268

(57) ABSTRACT

Disclosed are a display device including a display module including a panel part, in which a plurality of pixels are disposed, and a rear part supporting the panel part, and a display flexible printed circuit board (FPCB) module connected to the display module, and the display FPCB module may include a guide structure disposed at a first position of a rear surface of the display FPCB module to contact a portion of the rear part of the display module when the display FPCB module is in a folded state, a signal line connected to the guide structure, and a connector connected to the signal line, and a portable communication device including the same.

### CROSS-REFERENCE TO RELATED APPLICATIONS

This application is a continuation of International Application No. PCT/KR2025/003307 designating the United States, filed on Mar. 14, 2025, in the Korean Intellectual Property Receiving Office and claiming priority to Korean Patent Application No. 10-2024-0100681, filed on Jul. 30, 2024 and Korean Patent Application No. 10-2024-0082092, filed on Jun. 24, 2024, in the Korean Intellectual Property Office, the disclosures of each of which are incorporated by reference herein its their entireties.

### BACKGROUND

### 1. Field

The disclosure relates to a display device that may provide a uniform structure, and a portable communication device including the same.

### 2. Description of Related Art

A portable communication device, such as a smartphone, may provide various functions, such as a call function, based on various types of applications. In relation to such functional support, the portable communication device may include a communication circuit and an antenna. As an internal space becomes narrower in relation to the light weight and the large size of the portable communication device, at least a part of a housing of the portable communication device is used as an antenna. Various structures disposed inside or outside the housing of the portable communication device may affect communication characteristics of an antenna.

### SUMMARY

According to an example embodiment, a display device includes: a display module including a panel part comprising a display panel, in which a plurality of pixels are disposed, and a rear part comprising a support supporting the panel part, and a display flexible printed circuit board (FPCB) connected to the display module, wherein the display FPCB module may include a guide disposed at a first position of a rear surface of the display FPCB module and configured to contact a portion of the rear part of the display module based on the display FPCB module being in a folded state, a signal line connected to the guide, and a connector connected to the signal line.

According to an example embodiment, a portable communication device includes: a display device, and a housing, on which the display device is positioned, at least a portion of which comprises a metallic material, and having a side wall configured to be uses as an antenna, the display device includes a display module including a panel part comprising a display panel, in which a plurality of pixels are disposed, and a rear part comprising a support supporting the panel part, and a display flexible printed circuit board (FPCB) module connected to the display module, and including a folding area located within a specific distance at the side wall while being positioned on the housing, the display FPCB module includes a guide disposed at a first position of a rear surface of the display FPCB module and configured to contact a portion of the rear part of the display module based on the display FPCB module being in a folded state, a signal line connected to the guide, and a connector connected to the signal line.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram illustrating an example configuration of a portable communication device according to various embodiments;

FIG. 2 is an exploded perspective view illustrating a portable communication device according to various embodiments;

FIG. 3 is a diagram illustrating an example of a part of a configuration of a housing of a portable communication device according to various embodiments;

FIG. 4 is a cross-sectional view illustrating an example of a part of a portable communication device according to various embodiments;

FIG. 5 is a diagram illustrating an example of a rear surface of an example display device according to various embodiments;

FIG. 6 is a diagram illustrating an example of a rear surface of a display device when a FPCB module is in a state before being folded according to various embodiments;

FIG. 7 is a diagram illustrating an example of a rear surface of an example display device according to various embodiments;

FIG. 8 is a cross-sectional view illustrating a part of a portable communication device of FIG. 7 according to various embodiments;

FIG. 9 is a diagram illustrating an example of a rear surface of an example display device according to various embodiments;

FIG. 10 is a diagram illustrating an example of a rear surface of an example display device according to various embodiments;

FIG. 11 is a perspective view illustrating an example display device, in which a second type FPCB module is folded, according to various embodiments;

FIG. 12 is a perspective view illustrating an example display device, in which a second type FPCB module is folded, according to various embodiments;

FIG. 13 is a circuit diagram illustrating an example of at least a portion of a detection circuit according to various embodiments;

FIG. 14 is a circuit diagram illustrating a circuit for determining a normal state using detection of a capacitance according to various embodiments; and

FIG. 15 is a flowchart illustrating an example of an antenna tuning method of a portable communication device according to various embodiments.

### DETAILED DESCRIPTION

Hereinafter, various example embodiments of the disclosure will be described with reference to accompanying drawings.

An embodiment of the disclosure described below relates to a display flexible printed circuit board (FPCB) module (or a display FPCB, a display FPCB structure, a display FPCB assembly, an FPCB structure, or an FPCB device), and the display device (or a display structure or a display assembly) may include a display module (or a display part or a display) and a display FPCB module, and the display FPCB module may include a display processor (e.g., a DDIC, a display driving integrated chip) (or a processor) related to driving of the display module.

In the following description, a structure, in which a display processor related to driving of the display module may be disposed on a display FPCB, is illustrated and described, but the disclosure is not limited thereto. For example, the display processor may be disposed on one side (e.g., a panel part of the display module) of the display module. The display module of the disclosure may include an on cell touch AMOLED (OCTA) structure, but the disclosure is not limited thereto.

The portable communication device according to an example embodiment of the disclosure, in a process of folding the display FPCB module of the display device and fixing it onto a rear surface (e.g., an opposite surface to a front surface when a portion of the display module, at which a screen is displayed, is defined as the front surface), a folding position and a folding length or a folded state of the display FPCB module may be uniformly supported for each portable communication device using a guide structure (or a marker, a guide pad, a protrusion, or a reference structure) disposed at a portion of the display FPCB module.

The portable communication device according to an example embodiment of the disclosure may help the portable communication devices to have uniform communication characteristics by uniformly forming the folded state of the display FPCB module for each portable communication device. In this process, the portable communication device of the disclosure may achieve factory automation by designing an assembly jig to work on folding of the display FPCB module with reference to a guide structure, so that the portable communication device may not only secure mass production gains from factory automation but also have more uniform characteristics.

The various example embodiments of the disclosure may reduce a radiation deviation for each device, which is caused due to an attachment deviation of the display FPCB module, and may support detecting whether the display FPCB is assembled normally in various processing processes or use processes.

Furthermore, various purposes and effects provided by the display device and the portable communication device including the same according to various embodiments may be mentioned according to embodiments of the detailed description.

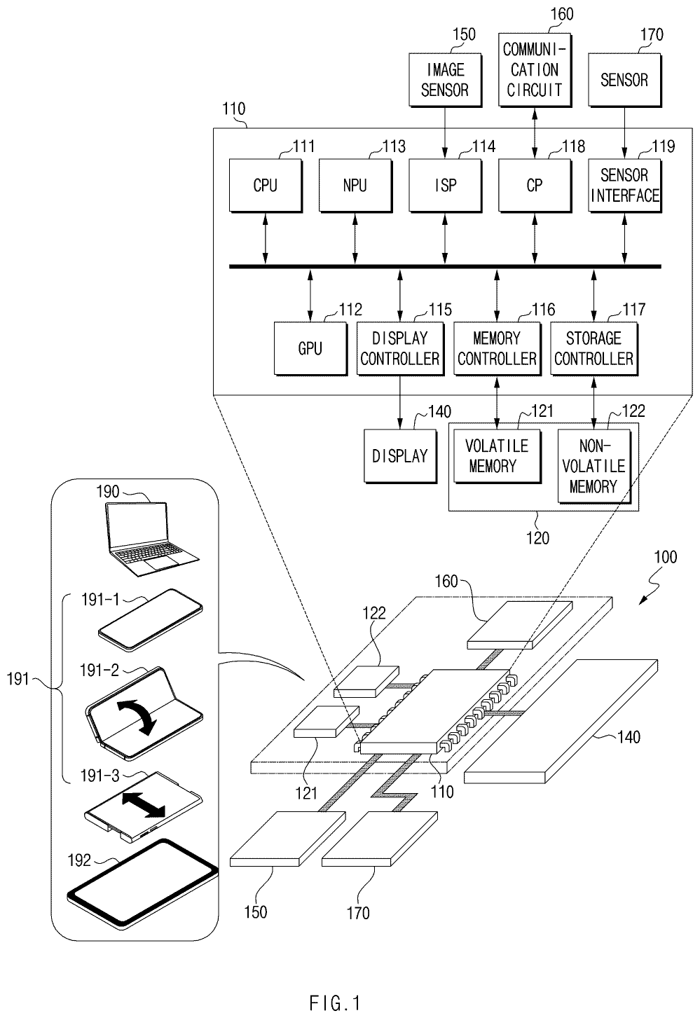

FIG. 1 is a block diagram illustrating an example configuration of a portable communication device 100 that may perform operations described in the disclosure according to various embodiments.

Referring to FIG. 1, the portable communication device 100 may be one of various types of electronic devices, such as a notebook 190, a smartphone 191 (e.g., a bar-type smartphone 191-1), a foldable-type smartphone 191-2, or a slidable (or rollable) type smartphone 191-3) with various form factors, a tablet 192, a cellular phone (not illustrated), and other similar computing devices (not illustrated). The components illustrated in FIG. 1, relationships thereof, and functions thereof are examples, and do not limit the implementations described or claimed in the disclosure. The portable communication device 100 may be referred to as a mobile device, a user device, a multi-functional device, a portable device, or a server.

The portable communication device 100 may include components including at least one processor (e.g., including processing circuitry) 110 (or a main processor, hereinafter referred to as a processor 110, at least one memory 120 (hereinafter referred to as a memory 120), at least one display device (e.g., including a display) 140, at least one image sensor 150 (hereinafter referred to as an image sensor 150), at least one communication circuit 160 (hereinafter referred to as a communication circuit 160), and/or at least one sensor 170 (hereinafter referred to as sensor 170). The above components are merely examples. For example, the portable communication device 100 may include other components (e.g., a power management integrated circuitry (PMIC), an audio processing circuitry, an antenna, a rechargeable battery, or an input/output interface). For example, some components may be omitted from the portable communication device 100. For example, some components may be incorporated into a single component.

The processor 110 may be implemented with one or more integrated circuit (or circuitry) (IC) chips, and may execute various data processing. The processor 110 may include at least one electrical circuit, and may distribute and process instructions (or programs, data, etc.) stored in the memory 120 individually or collectively. The processor 110 may include a set of processors including one or more processing circuits. The processor 110 may include any processing circuit that is operative to control the performance and operation of one or more components (e.g., the memory 120, the display device 140, the image sensor 150, the communication circuit 160, and/or the sensor 170) of the portable communication device 100. For example, the processor 110 (e.g., an application processor AP) may be implemented by a system on chip (SoC) (e.g., one chip or chipset). For example, the processor 110 may be implemented by a plurality of cores (or at least one core circuit), a plurality of chips, or a plurality of chipsets. For example, the processor 110 may include one or more processing circuits. For example, the processor 110 may include one or more processing circuits that are configured to perform various functions of the disclosure individually and/or collectively. As an unlimited example, at least a portion of the processor 110 may be included in a first chip of the portable communication device 100, and at least another portion of the processor 110 may be included in a second chip of the portable communication device 100, which is different from the first chip of the portable communication device 100.

For example, the processor 110 may include a central processing unit (CPU) 111, a graphics processing unit (GPU) 112, a natural processing unit (NPU) 113, an image signal processor (ISP) 114, a display controller 115, a memory controller 116, a storage controller 117, a communication processor (CP) 118, and/or a sensor interface 119. The components of the processor 110 are examples only. For example, the processor 110 may further include other components. For example, some components of the processor 110 may be omitted from the processor 110. For example, some components of the processor 110 may be included as separate components of the portable communication device 100 outside the processor 110. For example, some components (e.g., the memory controller 116) of processor 110 may be included in other components (e.g., at least portion of the memory 120, the interface (e.g., available for connection to at least one component of portable communication device 100), the display device 140, and/or the image sensor 150).

The processor 110 may cause other components of the portable communication device 100 to perform various operations by executing the instructions stored in the memory 120. The CPU 111 (or a central processing circuit) may be configured to control components of the processor 110 based on the execution of the instructions stored in the memory 120 (e.g., a volatile memory 121 and/or a nonvolatile memory 122). The GPU 112 (or a graphics processing circuit) may be configured to execute parallel operations (e.g., rendering). The NPU 113 (or a neural processing circuit, or an artificial intelligence (AI) chip) may be configured to execute operations (e.g., convolution computations) for an artificial intelligence model. The ISP 114 (or an image signal processing circuit) may be configured to process a raw image acquired through the image sensor 150 in a suitable format for a component in the portable communication device 100 or a component of the processor 110. The display controller 115 (or a display control circuit or a display processing unit (DPU) may be configured to process an image acquired from the CPU 111, the GPU 112, the ISP 114, or the memory 120 (e.g., the volatile memory 121) in a suitable format for the display device 140. The memory controller 116 (or a memory control circuit) may be configured to control reading data from the volatile memory 121 and recording the data to the volatile memory 121. The storage controller 117 (or a storage control circuit) may be configured to control reading data from the nonvolatile memory 122 and recording the data to the nonvolatile memory 122. The CP 118 (a communication processing circuit) may be configured to process data acquired from a component of the processor 110 in a suitable format for transmission to another electronic device through the communication circuit 160, or to process data acquired from another electronic device through the communication circuit 160 in a suitable format for processing the component of the processor 110. For example, the communication circuit 160 may include one or more communication circuits. The sensor interface 119 (or a sensing data processing circuit or a sensor hub) may be configured to process data on the state of the portable communication device 100 and/or the state of a periphery of the portable communication device 100, which is acquired through the sensor 170, in a suitable format for a component of the processor 110.

The memory 120 may include one or more storage media (or one or more storage devices). For example, the memory 120 may include a memory assembly including one or more storage media. For example, the one or more storage media may include a permanent memory (e.g., the nonvolatile memory 122), such as a hard drive, a flash memory, or a read only memory (ROM), a semi-permanent memory (e.g., the volatile memory 121), such as a random access memory (RAM), a storage (or a storage assembly) of any other suitable type, or any combination thereof. The memory 120 may include a cache memory that is a memory of one or more different types, which is used to temporarily store data for the function or feature of the portable communication device 100. As an unlimited example, the cache memory may be included in the processor 110. The memory 120 may be fixedly embedded in the portable communication device 100, and may be incorporated onto one or more suitable types of components (e.g., a subscriber identity module (SIM) or cards and/or secure digital (SD) cards) that may be repeatedly inserted into the portable communication device 100 and removed from the portable communication device 100.

For example, the memory 120 may store one or more software applications, such as operating system (or system) software applications, firmware software applications, driver software applications, plug-in (e.g., add-in, add-on, and/or applet) software applications, and/or any other suitable software applications. For example, the one or more software applications may include instructions that may be executable by processor 110. For example, the memory 120 may store instructions that may be called by an application programming interface (API). For example, the memory 120 may store instructions in a library.

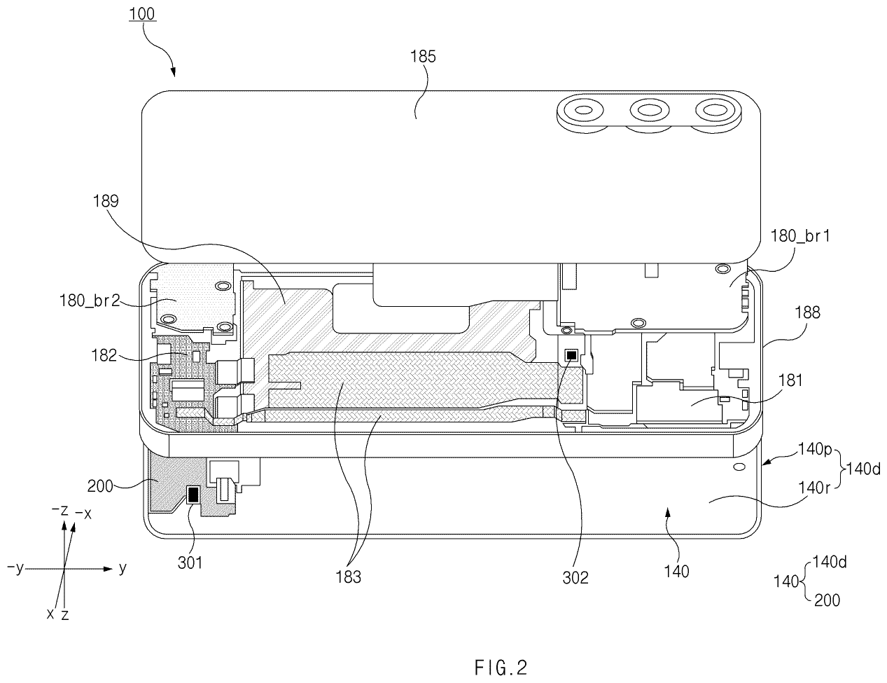

FIG. 2 is an exploded perspective view illustrating an example portable communication device according to various embodiments.

The portable communication device referred in FIG. 2 may, for example, be an example of the portable communication device described above with reference to FIG. 1.

Referring to FIGS. 1 and 2, the portable communication device 100 according to an embodiment may include a display device 140, a housing 188 (or a frame, a body, a support structure, or a bracket structure), and a rear cover 185 (or a cover or a rear surface case), and the housing 188 may include a first printed circuit board 181 (or a main printed circuit board (PCB)), a second printed circuit board 182 (or a sub PCB), a connection board 183 (or a connection cable, a connection wiring line, or a flexible PCB (FPCB)), a battery 189, a first bracket 180_br1 (or a first rear bracket or a first rear case), and a second bracket 180_br2 (or a second rear bracket or a second rear case).

At least a portion of the housing 188 may be formed of a metallic material. The housing 188 may be configured by processing at least a portion of a metal plate and at least partially adding an injection-molded structure through an injection-molding operation. At least a portion of the metal material of the housing 188 may be used as an antenna for the portable communication device 100. As an example, the housing 188 may include a bottom portion, of which at least a portion includes a curved structure and is formed in a polygonal plate shape as a whole, and a side wall that is formed along a periphery of the bottom portion and is formed in a direction that is perpendicular to the bottom portion (e.g., the −z-axis or z-axis direction). As an example, an overall shape of the bottom portion of the housing 188 may include a rectangular shape, and a side wall thereof may be disposed in a strip shape along a periphery of the bottom portion of the rectangular shape. At least a part of the side wall of the above-described structures may be formed of a metallic material, and at least a portion of the bottom portion may include an injection-molded structure. Alternatively, at least a portion of the side wall may include a structure formed of a metallic material and an injection-molded structure, and at least a portion of the bottom portion may include a structure of a metallic material and an injection-molded structure. According to an embodiment, the side wall of the housing 188 may be segmented by at least one slit that is formed in the z-axis direction (or the −z-axis direction). Correspondingly, the side wall may include a structure, in which a plurality of segmented portions are disposed in a strip shape, and at least one of an insulating material and an adhesive material may be filled in the slit.

At least a portion of the display device 140 may be seated in a direction of a front surface (e.g., a surface that faces the z-axis direction) of the housing 188. As an example, at least a portion of a rear surface (an opposite surface to the front surface, on which a screen is displayed) of the display device 140 may be positioned in a direction of a front surface of the bottom port of the housing 188, and, among the side walls of the housing 188, side wall parts that protrudes in the z-axis direction may be disposed to surround a periphery of the display device 140. A spacing space may be formed between the side wall parts that protrude in the z-axis direction of the housing 188 and a periphery of the display device 140. A first adhesion member may be further disposed between the display device 140, and a front surface of the bottom portion of the housing 188 and the side wall parts. The first adhesion member may fix at least a portion of the display device 140 in a direction of the front surface of the housing 188. Alternatively, the display device 140 may be fixed to the front surface of the housing 188 based on various structures or methods.

Electronic elements or other structures that are related to supporting various functions of the portable communication device 100 may be disposed in a direction of the rear surface (e.g., a surface that faces the −z-axis direction) of the housing 188. As an example, a bottom portion in a direction of the rear surface of the housing 188 may have a groove (or a hole), in which the battery 189 may be disposed (or seated). A rear surface of the bottom portion of the housing 188 may include a groove (or a hole), in which the first printed circuit board 181 and the second printed circuit board 182 may be disposed (or seated). The bottom portion of the housing 188 may include a hole (e.g., a hole that passes through the front and rear surfaces of the bottom portion of the housing 188) that is related to disposition of a wiring line, by which the display device 140 and the first printed circuit board 181 or the second printed circuit board 182 may be electrically connected to each other. A rear cover 185 that covers the rear surface (e.g., a surface that faces the −z-axis direction) of the bottom portion of the housing 188 may be disposed. A second adhesion member that fixes the rear cover 185 to the rear surface of the bottom portion of the housing 188 may be disposed between the rear surface of the bottom portion of the housing 188 and the rear cover 185. As an example, the second adhesion member may be disposed between the periphery of the rear cover 185 and the periphery of the rear surface of the bottom portion of the housing 188, or between the side wall parts that protrude from the periphery of the bottom portion of the housing 188 in the −z-axis direction. The rear cover 185 may be fixed to the housing 188 based on various structures or methods. A first bracket 180_br1 may be disposed between the rear cover 185 and the first printed circuit board 181, and the first bracket 180_br1 may be coupled to one side (e.g., a portion of a bottom portion, which is located at an upper end in the y-axis direction from a center of the portable communication device 100 (or with respect to the battery). A second bracket 180_br2 may be disposed between the rear cover 185 and the second printed circuit board 182, and the second bracket 180_br2 may be coupled to one side (or a portion of the bottom portion, which is located at a lower end of the −y-axis direction from the center of the portable communication device 100 (or with respect to the battery 189) of the bottom portion of the housing 188.

The rear cover 185 may be disposed to cover the rear surface of the housing 188. The rear cover 185 may have a shape that is similar to that of the housing 188. At least a portion of the rear cover 185 may include a structure (or part) that is formed of a nonmetallic material. The rear cover 185 may include at least one hole that passes in forward/rearward directions (e.g., the z-axis direction or the −z-axis direction). The at least one hole may include a camera hole that is related to at least one camera (or an image sensor) disposed within the housing 188 or a sensor hole that is related to at least one sensor 170.

The first printed circuit board 181 may be disposed at a portion (e.g., an upper end in the y-axis direction with respect to the battery 189) of the rear surface of the housing 188. The first printed circuit board 181 may include at least one electronic element. As an example, at least one processor 110 (e.g., a CPU or a GPU), at least one camera, at least one sensor, at least one memory 120, and at least one communication circuit 160 that are related to the operation of the portable communication device 100 may be disposed on the first printed circuit board 181. According to an embodiment, at least one of the first printed circuit boards 181 may include a microphone or a speaker. According to an embodiment, the first printed circuit board 181 may further include a detection circuit 302 that is related to detection of a folded state of a display FPCB module 200 according to an embodiment of the disclosure. The number of the detection circuits 302 may vary depending on the number of guide structures that are disposed in relation to the detection of the folded state of the display FPCB module 200. Alternatively, when the folded state of the display FPCB module 200 according to an embodiment of the disclosure is detected using a separate jig, a configuration of the detection circuit 302 may be omitted. A position of the detection circuit 302 may be changed. For example, the detection circuit 302 may be disposed on the second printed circuit board 182. Alternatively, the detection circuit 302 may be disposed in another structure (e.g., the display FPCB module 200).

The second printed circuit board 182 may be disposed at another portion (e.g., a lower end in the −y-axis direction with respect to the battery 189) of the rear surface of the housing 188. The second printed circuit board 182 may include at least one electronic element. As an example, at least one communication circuit 160 that is related to the operation of a communication function of the portable communication device 100 and a connection interface (e.g., a USB connector) that may be connected by wire may be disposed on the second printed circuit board 182. Additionally or alternatively, the second printed circuit board 182 may include at least one microphone or speaker. As an example, the second printed circuit board 182 may be functionally or electrically connected to the display device 140. In this regard, the bottom portion of the housing 188, on which the second printed circuit board 182 is mounted, may include at least one hole, through which a connector (e.g., a connector that is disposed on the display FPCB module 200) disposed on the display device 140 may be exposed in the direction of the rear surface of the housing 188.

The connection board 183 may include at least one of a cable, a wiring line, a film, a PCB, and an FPCB that may electrically connect the first printed circuit board 181 and the second printed circuit board 182. The connection board 183 may transmit a signal of the first printed circuit board 181 to the second printed circuit board 182, or a signal of the second printed circuit board 182 to the first printed circuit board 181. In the illustrated drawing, although a structure, in which at least a portion of the connection board 183 is positioned on the upper surface (e.g., a surface that is exposed in the direction of the rear cover) of the battery 189, is illustrated, the disclosure is not limited thereto. For example, at least a portion of the connection board 183 may be disposed between the battery 189 and the bottom portion (or the rear surface of the bottom portion) of the rear surface of the housing 188. Connector pins (or connector accommodating parts) may be disposed at opposite ends of the connection board 183, and each of the first printed circuit board 181 and the second printed circuit board 182 may include a connector accommodating (or a connector pin) that may be connected to each of opposite ends of the connection board 183.

The battery 189 may be seated on one side (e.g., a groove or a hole that is configured such that the battery 189 is seated therein) of the housing 188. For example, the battery 189 may supply electric power to the first printed circuit board 181 or electric power to the second printed circuit board 182. In this regard, the battery 189 may include a power management IC (PMIC) for charging and discharging electric power. As an example, the battery 189 may be adhered to the bottom portion of the rear surface of the housing 188, and the portable communication device 100 may further include a battery adhesion member for adhering the battery 189.

The first bracket 180_br1 may be disposed between the rear cover 185 and the first printed circuit board 181. For example, the first bracket 180_br1 may have a size that is the same as or similar to a size of the first printed circuit board 181 in at least one direction. The first bracket 180_br1 may be coupled to the bottom portion of the rear surface of the housing 188 while covering at least a portion of the first printed circuit board 181 to protect the first printed circuit board 181. According to an embodiment, at least one antenna pattern may be disposed on at least a portion of the first bracket 180_br1, and the antenna pattern printed on the first bracket 180_br1 may be electrically connected to the first printed circuit board 181.

The second bracket 180_br2 may be disposed between the rear cover 185 and the second printed circuit board 182. The second bracket 180_br2 may have a size that is the same as or similar to a size of the second printed circuit board 182 in at least one direction. The second bracket 180_br2 may be coupled to the bottom portion of the rear surface of the housing 188 while covering at least a portion of the second printed circuit board 182 to protect the second printed circuit board 182. According to an embodiment, at least one antenna pattern may be disposed on at least a portion of the second bracket 180_br2.

At least some of the structures of the housing 188, the structures of the first printed circuit board 181 and the second printed circuit board 182, the configurations of the first bracket 180_br1, the second bracket 180_br2, and the rear cover 185 described above may be omitted or replaced with other configurations.

The display device 140 may be positioned on the front surface (e.g., one surface in the z-axis direction) of the housing 188. According to an embodiment, at least a portion of the periphery of the display device 140 may be protected by the side wall parts disposed on the periphery of the front surface of the housing 188. According to an embodiment, the display device 140 (or the display assembly) may include a display module 140d (or a display) and a display FPCB module 200. The display module 140d may include a panel part 140p (or a panel layer) that displays a screen, and a rear part 140r (or a rear surface layer) that is disposed on the panel part 140p.

The panel part 140p may include, for example, a pixel layer (or a display panel, in which a plurality of pixels are disposed), on which a plurality of pixels related to display of a screen are disposed), and a touch layer (or a touch panel) that is disposed on the pixel layer to sense a user's touch. Additionally or alternatively, the panel part 140p may include a protective layer (or protective layers) that protects at least one of the pixel layer or the touch layer. A hole that is related to the operation of the front camera may be formed in at least one of the layers that comprise the panel part 140p.

The rear part 140r may include a plurality of layers. As an example, the rear part 140r may further include at least one of a first rear support layer that dissipates heat generated from the panel part 140p, a second rear support layer that absorbs the impact transmitted through the panel part 140p, and a third rear support layer that supports the rear surface of the panel part 140p, when observed from the −z axis to the z axis direction. The portable communication device 100 (or the display module 140d) may further include an adhesion layer that attaches the rear part 140r to the rear surface of the panel part 140p or adheres the first to third rear support layers. The rear part 140r may include only any one of the first to third rear support layers or may include all of the support layers. The rear part 140r may have an extent that is the same as or similar to the entire size of the panel part 140p, and may be disposed on a rear surface (e.g., one surface in the −z-axis direction) of the panel part 140p. At least a portion of the rear part 140r may be partially removed. Alternatively, any one of the plurality of rear support layers may be configured to have a size or shape that is different from the size or shape of the other support layer.

One side of the display FPCB module 200 may be coupled to the display module 140d, and at least a portion of an opposite side of the display FPCB module 200 may be fixed to the rear surface of the display module 140d. In this process, a folding area of the display FPCB module 200 may be disposed adjacent to a side wall part (e.g., a side wall part that is used as an antenna of a metallic material) of the housing 188. According to an embodiment, a guide structure may be disposed in the display FPCB module 200. The display FPCB module 200 may include a detection circuit 301 that is used to monitor a folding degree (or a folded state). The detection circuit 301 may replace the detection circuit 302 disposed on the first printed circuit board 181 as described above, may be replaced with the detection circuit 302, or may be further added independently of the detection circuit 302. The detection circuit 301 may be omitted from the display FPCB module 200 when the detection circuit 301 is disposed in an external device (e.g., a jig for inspecting a display) that is used to inspect the presence or absence of an abnormality in the display device 140.

As the display FPCB module 200 including the guide structure monitors a folded state of the display FPCB module 200 based on the guide structure, a folding degree of the display FPCB module 200 may be made uniform. Correspondingly, as a distance between the display FPCB module 200 and the side wall part of the housing 188 is constantly managed for each portable communication device 100, communication characteristics of the communication circuit 160 that uses at least a portion of the side wall of the housing 188 as an antenna may be uniformly designed.

As described above, the display device 140 according to an embodiment of the disclosure may include a guide structure that is disposed on at least a portion of the display FPCB module 200, and the folded state of the display FPCB module 200 of each of the portable communication devices 100 may be uniformly managed by identifying the folding degree or the folded state of the display FPCB module 200 using the guide structure in a process of folding the display FPCB module 200. Based on this, the display device 140 of the disclosure may manage to exhibit uniform communication characteristics for each portable communication device 100 in an environment, in which some side walls of a metallic material of the housing 188 are used as antennas.

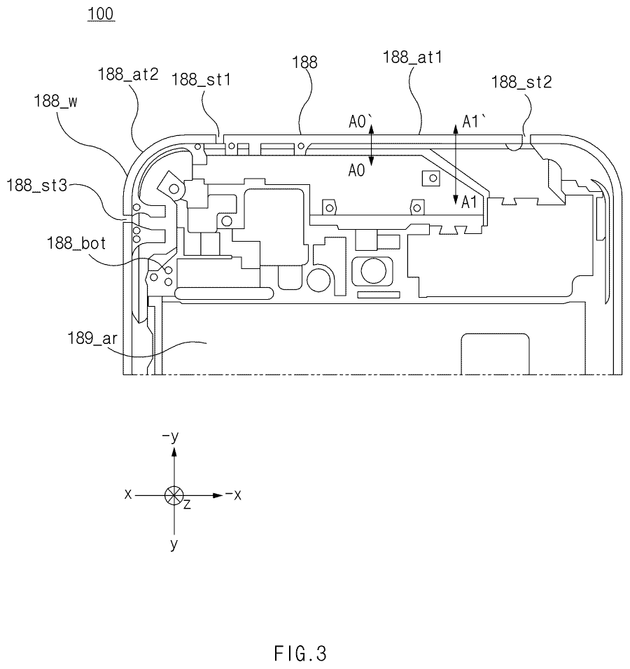

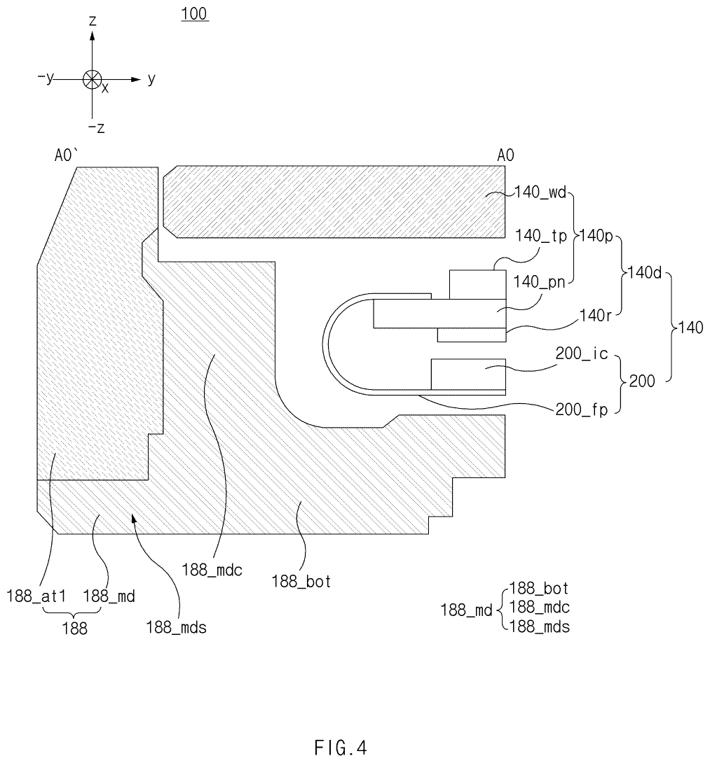

FIG. 3 is a diagram illustrating an example of a part of a configuration of a housing of a portable communication device according to various embodiments. FIG. 4 is a cross-sectional view illustrating an example of a part of a portable communication device according to various embodiments.

Referring to FIGS. 1, 2 and 3, the housing 188 according to an embodiment may include a bottom portion 188_bot, on which the first printed circuit board 181 (the first printed circuit board 181 of FIG. 2) is positioned, and a side wall 188 w that defines a periphery of the bottom portion 188_bot. A rear surface of the bottom portion 188_bot may include at least a battery area 189_ar, in which a battery (the battery 189 of FIG. 2) is disposed. As described above with reference to FIG. 2, the rear surface of the bottom portion 188_bot may further include an area, in which the second printed circuit board (the second printed circuit board 182 of FIG. 2) is positioned.

The side wall 188_w may include a plurality of slits 188_st1, 188_st2, and 188_st3 and a plurality of housing antennas 188_at1 and 188_at2. As an example, the side wall 188_w may include a first slit 188_st1 that is disposed at a periphery thereof in the −y-axis direction, a second slit 188_st2, and a third slit 188_st3 that is disposed in a periphery in the x-axis direction. The side wall 188_w may include a first housing antenna 188_at1 that is disposed between the first slit 188_st1 and the second slit 188_st2, and a second housing antenna 188_at2 that is disposed between the first slit 188_st1 and the third slit 188_st3. The side wall 188_w may further include at least one slit that is disposed in an area other than the three slits 188_st1, 188_st2, and 188_st3, and the side wall may further include at least one slit and at least one housing antenna that is isolated by the slits 188_st1, 188_st2, and 188_st3.

The slits 188_st1, 188_st2, and 188_st3 may segment the housing antennas 188_at1 and 188_at2 (or space them apart from each other by forming a gap of a specific size) by cutting a portion of the side wall 188_w, or may segment side wall parts that is different from the housing antennas 188_at1 and 188_at2 (or space them apart from each other by forming a gap of a specific size). Empty spaces or gaps corresponding to the slits 188_st1, 188_st2, and 188_st3 may be filled with at least an insulating material. A material (or a structure), in which an insulating material and an adhesive material are mixed, may be disposed in the slits 188_st1, 188_st2, and 188_st3. The housing antennas 188_at1 and 188_at2 may be electrically connected to the communication circuit 160 described above with reference to FIG. 1, and may be used for transmission and reception of signals of the communication circuit 160.

In an embodiment of the disclosure, the side wall 188_w presents a structure including a first housing antenna 188_at1 that is located between the first slit 188_st1 and the second slit 188_st2, which may be electrically influence or influenced by the display FPCB module 200 of the display device 140. In an embodiment of the disclosure, the direction, in which the display FPCB module 200 is folded, may be changed in the leftward/rightward direction (e.g., in the x-axis or −x-axis direction, the direction, in which the volume or power key is disposed or vice versa) with respect to the center of the portable communication device 100, and when the housing antennas are formed by portions of the left and right side walls, the direction or position of the display FPCB module 200 including the guide structure of the disclosure may be changed and applied.

Referring to FIGS. 1, 2, 3 and 4, as in a cross section taken along cutting line A0-A0′ of FIG. 3, the portable communication device 100 according to various embodiments may include at least the display device 140 and the housing 188.

The display device 140 may include the display FPCB module 200 and the display module 140d.

The display module 140d may include a panel part 140p and a rear part 140r. The panel part 140p may include a window 140_wd, a touch panel 140_tp, and a display panel 140_pn. The panel part 140p may further include at least one adhesion layer that adheres the window 140_wd (or a protective layer), the touch panel 140_tp, and the display panel 140_pn. Alternatively, the panel part 140p may further include a polarizing plate. The rear part 140r may be disposed on a rear surface of the panel part 140p to support the panel part 140p. The rear part 140r may include, for example, at least one impact absorbing layer, and a metal layer (e.g., a Cu layer or a metal pattern layer). However, the display module 140d of the disclosure is not limited to the types or numbers of the panel parts 140p and the rear parts 140r described above, and the panel part 140p may include at least one layer that may support a function of displaying a screen, and the rear part 140r may be a configuration including at least one layer including a structure (or a part) of a metallic material.

The display FPCB module 200 may include a display processor 200_ic (or a processor or a display driving IC), and a display FPCB 200_fp. The display processor 200_ic may be disposed on the panel part 140p of the display module 140d. Alternatively, the display processor 200_ic may be disposed on the display FPCB 200_fp. The display FPCB 200_fp may be connected to the display panel part 140p, and at least a portion thereof may be folded. At least a portion of the folded portion may be disposed on the rear part 140r of the display module 140d.

Referring to FIG. 4 illustrating a cross section taken along cutting line A0-A0′ of FIG. 3, the housing 188 of the portable communication device 100 according to an embodiment may include at least an injection-molded part 188_md and a first housing antenna 188_at1.

The injection-molded part 188_md may include a nonmetallic material structure (or a nonmetallic part). As an example, the injection-molded part 188_md may include a bottom portion 188_bot, a housing injection-molded side wall 188_mdc that protrudes from the bottom portion 188_bot in the z-axis direction, and an injection-molded support portion 188_mds that contacts the first housing antenna 188_at1.

The bottom portion 188_bot may comprise a bottom of the housing 188. The bottom portion 188_bot may include a plate shape, of which the length in the x-axis or y-axis is greater than the size in the z-axis. As described above, the bottom portion 188_bot may provide a space, in which various elements of the portable communication device 100 may be disposed, and may support at least some of the disposed various elements. As an example, at least a portion of the display device 140 may be positioned in a direction (e.g., the z-axis direction) of a front surface of the bottom portion 188_bot, and the battery 189 or at least one printed circuit board 181 or 182 and the rear cover 185 may be disposed in a direction (e.g., the −z-axis direction) of a rear surface of the bottom portion 188_bot.

The housing injection-molded side wall 188_mdc may be disposed at a periphery (e.g., a periphery on the xy plane) of the bottom portion 188_bot. As an example, the housing injection-molded side wall 188_mdc may extend from the front surface of the bottom portion 188_bot to a certain height in the z-axis direction. The housing injection-molded side wall 188_mdc may be disposed between the periphery of the bottom portion 188_bot and the injection-molded support portion 188_mds, and a height of an upper end of the housing injection-molded side wall 188_mdc may be greater than a height of the injection-molded support portion 188_mds in the z-axis direction or a height of the bottom portion 188_mdc in the z-axis direction. As an example, at least a portion of the housing injection-molded side wall 188_mdc may include a portion that is disposed between the bottom portion 188_bot of the housing and the injection-molded support portion 188_mds, and protrudes further in the z-axis direction than the height of one surface of the bottom portion 188_bot (e.g., the surface that faces the z-axis) or one surface (a surface that faces the z axis) of the injection-molded support portion 188_mds. The housing injection-molded side wall 188_mdc may define a stepped shape that faces the −y-axis direction together with the injection-molded support portion 188_mds. One surface (e.g., the surface that faces the −y axis) of the housing injection-molded side wall 188_mdc may be disposed to face (or contact) one surface (e.g., the surface that faces the y axis) of the first housing antenna 188_at1. The housing injection-molded side wall 188_mdc may be formed of the same material (e.g., a nonmetallic material) as that of the injection-molded support portion 188_mds and the housing bottom portion 188_bot. A height (or a height of an upper end of the housing injection-molded side wall 188_mdc) of the housing injection-molded side wall 188_mdc in the z-axis direction may be formed lower than a height of the first housing antenna 188_at1 in the z-axis direction (or a height of an upper end of the first housing antenna 188_at1). As an example, an upper end of the housing injection-molded side wall 188_mdc may define a stepped shape together with an upper end of the first housing antenna 188_at1. A portion (e.g., window 140_wd) of the display device 140 may be disposed on at least a portion of an upper end of the housing injection-molded side wall 188_mdc. At least a portion of the upper end of the housing injection-molded side wall 188_mdc may support at least a portion of the periphery of the display device 140.

The bottom portion 188_bot and the housing injection-molded side wall 188_mdc may define a groove, in which at least a portion of the display device 140 may be seated. At least a portion of the periphery of the display device 140 may face one surface (e.g., a surface that faces the y-axis direction) of the housing injection-molded side wall 188_mdc. As an example, the display FPCB 200_fp electrically connected to at least one of the display panel 140_pn and the touch panel 140_tp may be folded from the z-axis direction to the −z-axis direction, and the folded area (e.g., the curved area) of the display FPCB 200_fp may be disposed adjacent to a corner area defined by the bottom portion 188_bot and the housing injection-molded side wall 188_mdc. Because the display FPCB 200_fp includes at least a metal wiring line, the display FPCB 200_fp may electrically affect the first housing antenna 188_at1. The display FPCB 200_fp of the disclosure may constantly form the folding shape of the display FPCB 200_fp using a guide structure, so that a constant distance between the display FPCB 200_fp (or the display processor 200_ic) of each of the portable communication devices 100 and the first housing antenna 188_at1 may be maintained to support uniform communication characteristics.

The injection-molded support portion 188_mds may include a shape that protrudes from a portion (e.g., a lower end portion in the −z-axis direction) of the housing injection-molded side wall 188_mdc in the −y-axis direction. As an example, the injection-molded support portion 188_mds may support a lower end portion (e.g., a portion in the −z-axis direction) of the first housing antenna 188_at1. In this regard, one surface (e.g., a surface that faces the z-axis direction) of the injection-molded support portion 188_mds may contact the lower end portion (or a surface that faces the −z-axis direction) of the first housing antenna 188_at1. The thickness of the injection-molded support portion 188_mds in the z-axis direction may be smaller than the thickness of the first housing antenna 188_at1 in the z-axis direction. The y-axis length of the injection-molded support portion 188_mds may be formed to be the same as or similar to the y-axis thickness of the first housing antenna 188_at1.

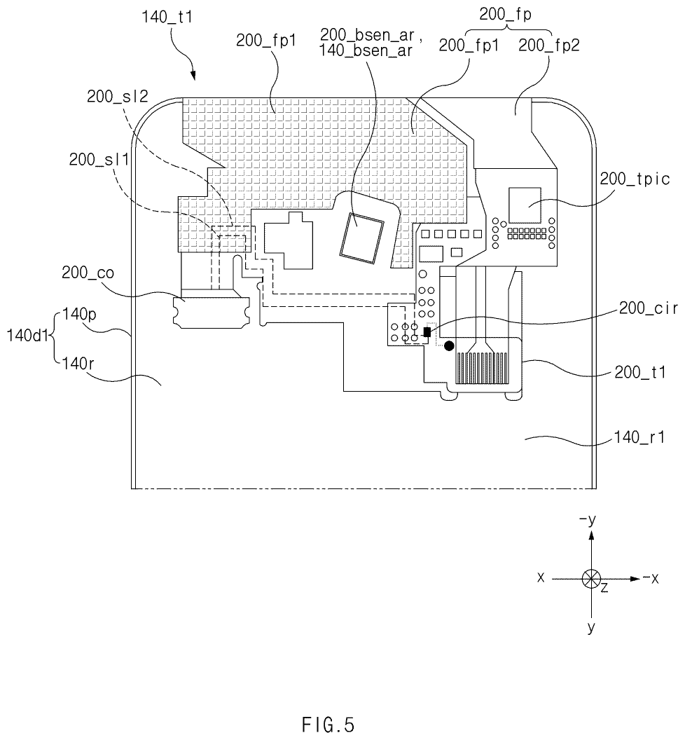

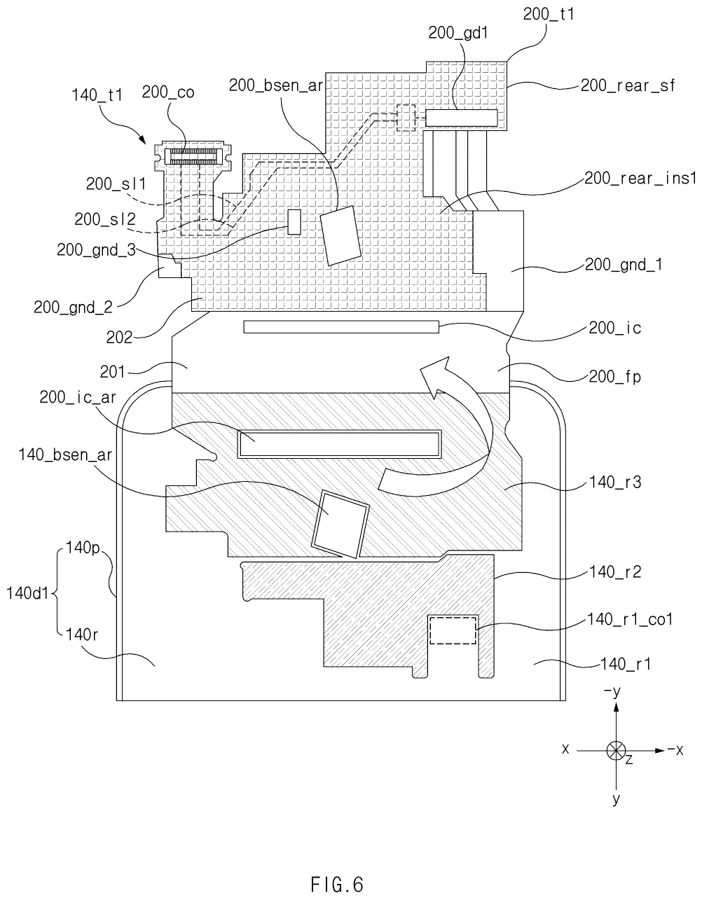

FIG. 5 is a diagram illustrating an example of a rear surface of an example display device according to various embodiments. FIG. 6 is a diagram illustrating an example of a rear surface of an example display device when a first type FPCB module is in a state before being folded according to various embodiments.

Referring to FIGS. 1, 2, 3, 4, 5 and 6, a display device 140_t1 may include a display module 140d1 and a first type FPCB module 200_t1 (or a display FPCB module).

The display module 140d1 may include a panel part 140p and a rear part 140r. The panel part 140p may include the same configuration as at least some of the components of the panel part 140p described above with reference to FIG. 4.

The rear part 140r may have a configuration that is the same as or similar to that of the rear part 140r described above with reference to FIG. 4. As an example, the rear part 140r may include a plurality of layers including a metal layer. Alternatively, the rear part 140r may include a first rear support layer 140_r1, a second rear support layer 140_r2, and a third rear support layer 140_r3.

The first rear support layer 140_r1 may include a metal layer (or a Cu layer). The first rear support layer 140_r1 may be disposed over the overall rear surface of the display. The first rear support layer 140_r1 may be disposed in an area other than an area, in which the second rear support layer 140_r2 (or at least one of the second rear support layer 140_r2 and the third rear support layer 140_r3) is formed, among all areas of the rear surface of the display. The first rear support layer 140_r1 may support the panel part 140p. The first rear support layer 140_r1 may dissipate at least a portion of heat generated by the panel part 140p.

At least a portion of the first rear support layer 140_r1 may be removed and the second rear support layer 140_r2 may be exposed. The second rear support layer 140_r2 may be disposed between the panel part 140p and the first rear support layer 140_r1 with respect to the Z-axis direction. With respect to the Y-axis direction, the second rear support layer 140_r2 may be disposed between the third rear support layer 140_r3 and a portion of a lower end of the first rear support layer 140_r1. At least a portion of the second rear support layer 140_r2 may be formed similar to a portion (a portion of the second part 202 of FIG. 6) of the first type FPCB module 200_t1. An adhesive material may be applied or an adhesion member may be disposed on the second rear support layer 140_r2. At least a portion of the second rear support layer 140_r2 may be formed to surround at least a portion of the first structural contact area 140_r1_co1 formed as a portion of the first rear support layer 140_r1. The second rear support layer 140_r2 may serve as an impact absorbing layer of the panel part 140p. The second rear support layer 140_r2 may be formed of a nonconductive material. As an example, at least a portion of the second rear support layer 140_r2 may be formed of sponge or a plurality of embosses of a nonconductive material.

The third rear support layer 140_r3 may include an adhesion layer that is separately adhered onto the first rear support layer 140_r1. At least a portion of the third rear support layer 140_r3 may include a shape corresponding to at least a portion of the shape of a rear surface (e.g., a surface illustrated in FIG. 6) of the first type FPCB module 200_t1. The third rear support layer 140_r3 may include a conductive adhesion member. The third rear support layer 140_r3 may fix at least a portion of the first type FPCB module 200_t1 to the rear part 140r. While the first type FPCB module 200_t1 is folded, a partial area of the third rear support layer 140_r3 corresponding to an area, in which the display processor 200_ic is disposed, may be removed. Alternatively, while the first type FPCB module 200_t1 is folded, an area of the third rear support layer 140_r3 and the first rear support layer 140_r1 corresponding to an area, in which the display processor 200_ic is disposed, is removed to become an area 200_ic_ar, in which the second rear support layer 140_r2 is exposed. The third rear support layer 140_r3 may be disposed within a first distance from a periphery (e.g., −y-axis periphery) of one side of the panel part 140p (or the display panel 140_pn of FIG. 4), and a portion of the second rear support layer 140_r2, from which the first rear support layer 140_r1 is removed and exposed, may be disposed within a second distance from a periphery (e.g., y-axis periphery) of one side of the third rear support layer 140_r3.

The rear part 140r may include a first area 140_bsen_ar, in which a biometric sensor is disposed. The first area 140_bsen_ar may be formed to pass through the first rear support layer 140_r1, the second rear support layer 140_r2, and the third rear support layer 140_r3 in the z-axis direction. When the first type FPCB module 200_t1 is in a folded state, the first area 140_bsen_ar may be aligned with a second area 200_bsen_ar formed in the first type FPCB module 200_t1.

The first type FPCB module 200_t1 may include a display FPCB 200_fp (e.g., a first FPCB 200_fp1 (or a display panel FPCB), a second FPCB 200_fp2 (or a touch panel FPCB)), a touch processor 200_tpic, a connector 200_co, a detection circuit 200_cir, a first signal line 200_sl1, and a second signal line 200_sl2. The detection circuit 200_cir may be omitted. When the detection circuit 200_cir is omitted from the first type FPCB module 200_t1, the first type FPCB module 200_t1 may include only one signal line (e.g., any one of a first signal line 200_sl1 and a second signal line 200_sl2) that connects the guide structure and the connector 200_co.

The FPCB module 200_t1 may further include a biometric sensor module. In relation to the disposition of the biometric sensor module, the display device 140_t1 may include a biometric sensor area 140_bsen_ar and 200_bsen_ar. The biometric sensor area 140_bsen_ar and 200_bsen_ar may include a first area 140_bsen_ar, in which at least a portion of the rear part 140r is removed and a rear surface (e.g., the display panel 140_pn) of the panel part 140p is exposed. Furthermore, the biometric sensor area 140_bsen_ar and 200_bsen_ar may include a second area 200_bsen_ar, in which a portion of the first FPCB 200_fp1 is removed (or a portion of the second part 202 of the first type FPCB module 200_t1 is removed). The biometric sensor area 140_bsen_ar and 200_bsen_ar may include an area, in which the first area 140_bsen_ar and the second area 200_bsen_ar overlap each other in the z-axis direction.

Referring to FIGS. 1, 2, 3, 4 and 5, the first FPCB 200_fp1 may be electrically connected to pads (or metal signal terminals related to pixel driving) disposed at a periphery of on a front surface (e.g., a surface that faces the z-axis direction) of the display panel 140_pn. The first FPCB 200_fp1 may be electrically connected to a display processor 200_ic (e.g., display driving integrated chips DDIC) disposed at a periphery of a front surface of the display panel 140_pn. The first FPCB 200_fp1 may be connected to a printed circuit board (e.g., at least one of the first PCB 181 and the second PCB 182 of FIG. 2) through the connector 200_co, and may transmit a signal transmitted from a main processor (e.g., CPU or GPU) mounted on the printed circuit board to the display panel 140_pn. In this regard, the first FPCB 200_fp1 may include at least one wiring layer (or a metal pattern layer) and at least one insulating layer. At least a portion of the first signal line 200_sl1 and the second signal line 200_sl2 may be disposed on at least one wiring layer of the first FPCB 200_fp1. At least one insulating layer of the first FPCB 200_fp1 may be disposed to cover at least a portion of the first signal line 200_sl1 and the second signal line 200_sl2. According to an embodiment, when the detection circuit 200 circuit is omitted from the first type FPCB module 200_t1, at least a portion of any one of the first signal line 200_sl1 and the second signal line 200_sl2 may be disposed on at least one wiring layer of the first FPCB 200_fp1.

A portion of the second FPCB 200_fp2 may be electrically connected to the touch processor 200_tpic, and another portion thereof may be electrically connected to the touch panel (the touch panel 140_tp of FIG. 4). The second FPCB 200_fp2 may transmit a signal generated by the touch processor 200_tpic to the touch panel (the touch panel 140_tp of FIG. 4) or a signal change generated by the touch panel (the touch panel 140_tp of FIG. 4) to the touch processor 200_tpic. The second FPCB 200_fp2 may include a wiring line that is electrically connected to the connector 200_co. The second FPCB 200_fp2 may include at least one wiring layer (or a metal pattern layer) and at least one insulating layer. The number of wiring layers and the number of insulating layers of the first FPCB 200_fp1 and the second FPCB 200_fp2 may be different from each other. The length of the first FPCB 200_fp1 in the x-axis direction and the length of the second FPCB 200_fp2 in the x-axis direction may vary depending on an observation position. A form, in which the first FPCB 200_fp1 and the second FPCB 200_fp2 are separated, has been illustrated in the above description, but the disclosure is not limited thereto. For example, the first FPCB 200_fp1 and the second FPCB 200_fp2 may be integrated with each other or at least a portion of the first FPCB 200_fp1 and the second FPCB 200_fp2 may be disposed on the rear part 140r of the display module 140d1 after the first FPCB 200_fp1 and the second FPCB 200_fp2 are fixed on a specific film or adhesion member.

The touch processor 200_tpic may be mounted on one side of the second FPCB 200_fp2. The touch processor 200_tpic may supply a signal for driving the touch panel (the touch panel 140_tpic of FIG. 4) to the touch panel (the touch panel 140_tpic of FIG. 4) according to a control signal transmitted through the connector 200_co (or through the second FPCB 200_fp2 connected to the connector 200_co). The touch processor 200_tpic may sense a signal change on the touch panel (the touch panel 140_tpic of FIG. 4), and transmit the sensed signal change to the printed circuit board (e.g., at least one of the first PCB 181 and the second PCB 182 of FIG. 2) through the connector 200_co.

The connector 200 co may include terminals that are electrically connected to the first FPCB 200_fp1 and terminals that are electrically connected to the second FPCB 200_fp2. The connector 200_co according to an embodiment of the disclosure may include terminals that are connected to the first signal line 200_sl1 and the second signal line 200_sl2. In the display device 140_t1, a structure, in which two signal lines 200_sl1 and 200_sl2 are connected to the connector 200_co, is illustrated, but the disclosure is not limited thereto. For example, the connector 200_co may include a terminal that is connected to one signal line. As an example, when the detection circuit 200-cur is omitted from the first type FPCB module 200_t1, the connector 200_co may include a terminal that is connected to any one of the first signal line 200_sl1 and the second signal line 200_sl2.

The detection circuit 200_cir may include at least one element. As an example, the detection circuit 200_cir may include distribution resistance elements for distribution of voltages of electric power supplied to the first guide structure 200_gd1. The detection circuit 200_cir may include the detection circuit 301 described above with reference to FIG. 2. In relation to the detection of the folded state of the display FPCB module 200, the detection circuit 200_cir may be omitted when a separate inspection jig that is connected to the connector 200_co is used. The inspection jig may supply designated test power through the connector 200_co and the first signal line 200_sl1, determine the signal received through the connector 200_co and the second signal line 200_sl2, and determine the disposition state of the first guide structure 200_gd1 to determine the folded state of the display FPCB module 200.

The first signal line 200_sl1 may electrically connect the connector 200_co and the detection circuit 200_cir. In this regard, the first signal line 200_sl1 may include a conductive material (or member). For example, at least a portion of the first signal line 200_sl1 may connect the detection circuit 200_cir and the connector 200_co through at least one of the first FPCB 200_fp1 and the second FPCB 200_fp2. The first signal line 200_sl1 may be formed on at least one metal layer of the first FPCB 200_fp1 and the second FPCB 200_fp2, and may have a state of being isolated (electrically spaced apart) from other metal patterns formed on the same metal layer.

The second signal line 200_sl2 may be disposed between the connector 200_co and the detection circuit 200_cir. For example, at least a portion of the second signal line 200_sl2 may electrically connect the connector 200_co and the detection circuit 200_cir through at least one of the first FPCB 200_fp1 and the second FPCB 200_fp2. In this regard, the second signal line 200_sl2 may be formed of a conductive material (or a conductive member). At least a portion of the second signal line 200_sl2 may be disposed in parallel with the first signal line 200_sl1. The second signal line 200_sl2 may be a signal line for detecting a signal change according to whether the first guide structure 200_gd1 and the rear part 140r of the display device 140 contact each other. The second signal line 200_sl2 may be formed on at least one metal layer of the first FPCB 200_fp1 and the second FPCB 200_fp2, and may have a state of being isolated (electrically spaced apart) from other metal patterns formed on the same metal layer. Alternatively, the second signal line 200_sl2 may be disposed on the same metal layer (e.g., at least one of the metal pattern layer of the first FPCB 200_fp1 and the metal pattern layer of the second FPCB 200_fp2) as that of the first signal line 200_sl1. The disclosure is not limited thereto, and the second signal line 200_sl2 may be disposed on a metal layer that is different from the metal layer of the first FPCB 200_fp1 (or the second FPCB 200_fp2), on which the first signal line 200_sl1 is disposed.

According to an embodiment, when the detection circuit 200_cir is removed from the first type FPCB module 200_t1, any one of the first signal line or the second signal line may be disposed between the first guide structure 200_gd1 and the connector 200_co. Any one of the first signal line or the second signal line may be used to sense a signal change depending on a contact state between the first guide structure 200_gd1 and the rear part 140r of the display device 140.

Referring to FIGS. 1, 2, 3, 4, 5 and 6, the FPCB module 200_t1 may have a partially different stack type. For example, the number of first stacks of the first part 201 of the first type FPCB module 200_t1, among the first type FPCB modules 200_t1, which is located within a third distance from the display module 140d1, and the number of second stacks of the second part 201 of the first type FPCB module 200_t1, which is located within a third distance to a fourth distance (e.g., a distance that is greater than the third distance) of the display module 140d1 may be different. As an example, the number of first stacks (e.g., the number of metal layers (or metal pattern layers or metal wiring layers) and the number of the insulating layers) may be smaller than the number of second stacks (e.g., the number of metal layers or insulating layers). According to an embodiment, the hardness of the first part 201 of the first type FPCB module 200_t1 may be different from the hardness of the second part 201 of the first type FPCB module 200_t1. As an example, the hardness of the first part 201 may be lower than that of the second part 202. Alternatively, the flexibility of the first part 201 may be greater than that of the second part 202 (more flexible).

According to an embodiment, the first guide structure 200_gd1, the signal lines 200_sl1 and 200_sl2, and the connector 200_co may be disposed in the second part 202. The display processor 200_ic may be disposed in the first part 201. At least a portion (e.g., the whole, except for the portion, at which the display processor 200_ic is disposed) of the first part 201 may be adhered to the third rear support layer 140_r3. A portion of the second part 202 may be adhered to the third rear support layer 140_r3, and the other portion of the second part 202 may be disposed on the first rear support layer 140_r1 or the second rear support layer 140_r2. An adhesive material (or an adhesion member) may be applied (or disposed) to the first part 201 and the second part 202 such that they are adhered to the rear part 140r. The first part 201 and the second part 202 are formed by dividing the shape of the first type FPCB module 200_t1 in an upward/downward direction (e.g., the y-axis or −y-axis direction). The first FPCB 200_fp1 and the second FPCB 200_fp2 may include a state, in which the shape of the first type FPCB module 200_t1 is divided in the leftward/rightward direction (e.g., the x-axis or −x-axis direction). Accordingly, the first FPCB 200_fp1 may be included in a portion of the first part 201 and the second part 202 described above, and the second FPCB 200_fp2 may be included in another portion of the first part 201 and another portion of the second part 202.

According to an embodiment, the first guide structure 200_gd1 may be disposed at a first position of the rear surface 200_rear_sf of the first type FPCB module 200_t1. For example, the first guide structure 200_gd1 may be disposed so that at least a portion thereof is exposed to a surface that faces the rear part 140r of the display module 140d1 when the rear surface 200_rear_sf (the first type FPCB module 200_t1 of the first type FPCB module 200_t1 is in a folded state. The first guide structure 200_gd1 may include a metal material (or a configuration formed of a metallic material). The first guide structure 200_gd1 may be formed as a portion of a specific metal layer of the first type FPCB module 200_t1 including a plurality of metal layers and insulating layers. As an example, a portion of the metal layer, which is disposed on the rear surface 200_rear_sf of the first type FPCB module 200_t1, may define a first guide structure 200_gd1. As an example, an FPCB rear surface insulating layer 200_rear_ins1 may be disposed on the rear surface 200_rear_sf of the first type FPCB module 200_t1. The first guide structure 200_gd1 may be formed by exposing a portion of the metal layer disposed under the FPCB rear surface insulating layer 200_rear_ins1 as a portion of the FPCB rear surface insulating layer 200_rear_ins1 is removed. The first guide structure 200_gd1 may be formed by applying (or disposing) a separate metal material on the FPCB rear surface insulating layer 200_rear_ins1.

According to an embodiment, among a plurality of metal layers that comprise the FPCB module 200_t1, the metal layer disposed in at least one layer (e.g., the rear surface 200_rear_sf) may include at least one ground area 200_gd_1, 200_gd_2, and 200_gd_3. The at least one ground area 200_gd_1, 200_gd_2, and 200_gd_3 may be formed by exposing a portion of the metal layer disposed under the FPCB rear surface insulating layer 200_rear_ins1 as the FPCB rear surface insulating layer 200_rear_ins1 is removed. The at least one ground area 200 gd_1, 200_gd_2, and 200_gd_3 may be disposed on the same metal layer. The at least one ground area 200_gd_1, 200_gd_2, and 200_gd_3 may be disposed on the same layer and may have an electrically connected state. When the first type FPCB module 200_t1 is folded, the at least one ground area 200_gd_1, 200_gd_2, and 200_gd_3 may be adhered to at least one of the third rear support layer 140_r3 and the first rear support layer 140_r1. The third rear support layer 140_r3 may be formed of a conductive adhesion member (e.g., a conductive double-sided tape). Accordingly, the at least one ground area 200_gd_1, 200_gd_2, and 200_gd_3 may serve as a ground terminal that is electrically connected to the first rear support layer 140_r1 through the third rear support layer 140_r3. The first guide structure 200_gd1 and the at least one ground area 200_gd_1, 200_gd_2, and 200_gd_3 may be spaced apart from each other. As an example, the first guide structure 200_gd1 may be disposed in the form of an island on a metal layer including the at least one ground area 200_gd_1, 200_gd_2, and 200_gd_3. The first signal line 200_sl1 and the second signal line 200_sl2 may be disposed on the same metal layer as the at least one ground area 200_gd_1, 200_gd_2, and 200_gd1.

While the FPCB module 200_t1 is folded and at least partially contacts the rear part 140r, the first guide structure 200_gd1 may contact the first structure contact area 140_r1_co1 corresponding to a partial area of the first rear support layer 140_r1. The first structure contact area 140_r1_co1 is a specific area of the first rear support layer 140_r1, and may be disposed in an area, at least a portion of which is surrounded by the second rear support layer 140_r2. The first structure contact area 140_r1_co1 may include a part (or structure) that is formed of a metallic material as it is configured as a part of the first rear support layer 140_r1. Accordingly, the first guide structure 200_gd1 may electrically contact the first rear support layer 140_r1 that serves as a ground through the first structure contact area 140_r1_co1. The position of a portion of the second rear support layer 140_r2, which surrounds the first structure contact area 140_r1_co1 or the first structure contact area 140_r1_co1, may be formed identically for each display device 140. While the first type FPCB module 200_t1 is folded and fixed onto the rear part 140r, the first guide structure 200_gd1 may be formed to contact the first structure contact area 140_r1_co1 surrounded by the second rear support layer 140_r2, so that the folded state of the first type FPCB module 200_t1 may be formed uniformly. Alternatively, the distance between the folding area of the first type FPCB module 200_t1 and the first housing antenna 188_at1 may be formed uniformly.

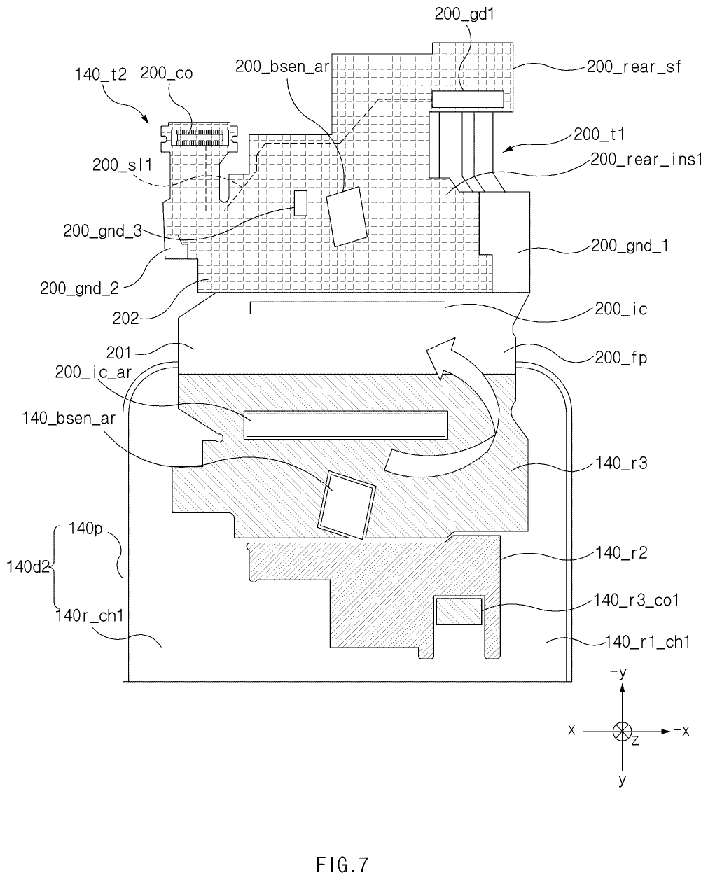

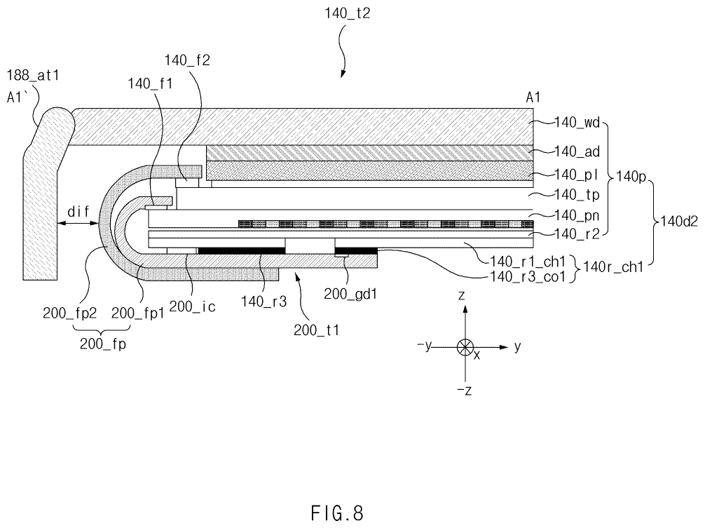

FIG. 7 is a diagram illustrating an example of a rear surface of an example display device according to various embodiments. FIG. 8 is a cross-sectional view illustrating an example of a part of a portable communication device of FIG. 7 according to various embodiments. As an example, one cross section of FIG. 8 is a cross section when the position of cutting line A1-A1′ illustrated in FIG. 3 is applied to the display device 140_t2 of FIG. 7. The cross section of FIG. 8 represents an example of a cross section that is obtained by folding the first type FPCB module 200_t1 of the display device 140_t2 of FIG. 7, fixing it to the first modified rear part 140r_ch1 of the display device 140_t2, and then cutting the position of cutting line A1-A1′ of FIG. 3. The display device 140_t2 of FIG. 7 may be presented through partial modification of the display device 140_t1. The display device 140_t2 of FIG. 7 may include a structure, in which the detection circuit 200_cur described in FIG. 5 or 6 is removed from the FPCB module. When the detection circuit is removed from the first type FPCB module 200_t1, one signal line (e.g., 200sl1) may connect the connector 200_co to the first guide structure 200_gd1.

Referring to FIGS. 1, 2, 3, 4, 5, 6, 7 and 8, the display device 140_t2 may include a first type FPCB module 200_t1 and a display module 140d2. The FPCB module 200_t1 illustrated in FIGS. 7 and 8 may have the same structure as that of the first type FPCB module 200_t1 described in FIGS. 5 and 6. For example, the first type FPCB module 200_t1 may include a first guide structure 200_gd1, a first signal line 200_sl1, a connector 200_co, and at least one ground area 200_gd_1, 200_gd_2, and 200_gd_3. The FPCB module 200_t1 includes a display FPCB 200_fp (e.g., the first FPCB 200_fp1 and the second FPCB 200_fp2) divided with respect to the x-axis direction, and may include a display processor 200_ic that is electrically connected to the first FPCB 200_fp1, a touch processor (the touch processor 200_tpic of FIG. 5) that is electrically connected to the second FPCB 200_fp2, and a detection circuit (the detection circuit 200_circuit of FIG. 5). When the display device 140_t2 further includes a detection circuit, the first type FPCB module 200_t1 described in FIG. 7 or 8 may include a plurality of signal lines that are connected to the detection circuit. Furthermore, the first type of FPCB module 200_t1 includes the first part 201 and the second part 202 divided with respect to the y-axis direction, and the corresponding configuration may have the same structure as those of the first part (e.g., the first part 201 of FIG. 6) and the second part (e.g., the second part 202 of FIG. 6) of the previous description of FIG. 5 and FIG. 6.

The display module 140d2 may have a configuration that is the same as or similar to that of the display module 140d1 described with reference to FIGS. 5 and 6, except for the structure adhesion area 140_r3_co1. For example, the display module 140d2 may include a panel part 140p and a first modified rear part 140r_ch1. According to an embodiment, the panel part 140p may include a window 140_wd, a first adhesion layer 140_ad, a polarization layer 140_p1, a touch panel 140_p1, and a display panel 140_pn. The window 140_wd may be adhered to the polarization layer 140_p1 through the first adhesion layer 140_ad.

The first FPCB 200_fp1 may be electrically connected to one end of the display panel 140_pn, at which a plurality of pixels are disposed through the first film 140_f1 (or a first anisotropic film, a first conductive film). A second film 140_f2, to which the second FPCB 200_fp2 is electrically connected, may be disposed at one end of the touch panel 140_tp. The second FPCB 200_fp2 may be electrically connected to one end of the touch panel 140_tp through the second film 140_f2 (or a second anisotropic film, a second conductive film).

The first modified rear part 140r_ch1 may include, for example, a first modified rear support layer 140_r1_ch1, a second rear support layer 140_r2, and a third rear support layer 140_r3. The second rear support layer 140_r2 and the third rear support layer 140_r3 may have a configuration that is the same as or similar to those of the second rear support layer and the third rear support layer described above with reference to FIGS. 5 and 6.

The first modified rear support layer 140_r1_ch1 may include a metal layer (or a Cu layer) and a structure adhesion area 140_r3_co1. The structure adhesion area 140_r3_co1 may include a conductive material and an adhesive material. As an example, the structure adhesion area 140_r3_co1 may include an area, in which a conductive adhesion member (e.g., a conductive double-sided tape) is disposed on the first modified rear support layer 140_r1_ch1. The conductive adhesion member disposed on the structure adhesion area 140_r3_co1 may be formed of the same material as that of the third rear support layer 140_r3. For example, the structure adhesion area 140_r3_co1 may be formed to be equal to or greater than the size of the first guide structure 200_gd1. The conductive adhesion member disposed in the structure adhesion area 140_r3_co1 may be disposed (or stacked) on the first modified rear support layer 140_r1_ch1 in the −z-axis direction. The conductive adhesion member may be formed to be smaller than the entire size of the first modified rear support layer 140_r1_ch1. At least a portion of the conductive adhesion member may be surrounded by at least a portion of the second rear support layer 140_r2.

As the FPCB module 200_t1 is folded, the first guide structure 200_gd1 may be operated to contact the structure adhesion area 140_r3_co1 while at least a portion of the first part 201 and the second part 202 of the first type FPCB module 200_t1 is adhered and fixed to the first modified rear part 140r_ch1, respectively. An inspection jig connected to the connector 200_co or a main processor (e.g., a CPU) included in the portable communication device as external equipment physically spaced apart from the portable communication device may determine whether the folded state of the FPCB module 200_t1 is good by identifying a signal depending on a contact state between the guide structure and the rear part. The inspection jig or the main processor may determine whether the first guide structure 200_gd1 contacts the structure adhesion area 140_r3_co1 when receiving a signal transmitted through a signal path including a first modified rear support layer 140_r1_ch1, to which the structure adhesion area 140_r3_co1 is electrically connected, a structure adhesion area 140_r3_co1 connected to the first guide structure 200_gd1, a first signal line 200_sl1 connected to the first guide structure 200_gd1, and a connector 200_co connected to the first signal line 200_sl1. When the first guide structure 200_gd1 and the structure adhesion area 140_r3_co1 are operated to electrically contact each other, a gap dif between the first housing antenna 188_at1 and the display FPCB 200_fp (e.g., the first FPCB 200_fp1 or the second FPCB 200_fp2) may be formed by a preset distance.

When the first guide structure 200_gd1 does not contact the structure adhesion area 140_r3_co1, the signal transmitted to the first signal line 200_sl1 connected to the first guide structure 200_gd1 may be different from the signal in the contact state. For example, the inspection jig or the main processor (e.g., the CPU), to which the connector 200_co connected to the first signal line 200_sl1 is connected, may determine a defect of the folded state of FPCB module 200_t1 when receiving a signal transmitted through a signal path including the first guide structure 200_gd1, the first signal line 200_sl1, and the connector 200_co that do not contact the structure adhesion area 140_r3_co1.

The display device 140_t2 described above may more firmly maintain a fixed state (or an adhesion state) of the first guide structure 200_gd1 by attaching the first guide structure 200_gd1 to the structure adhesion area 140_r3_co1, in which the conductive adhesion member is disposed.

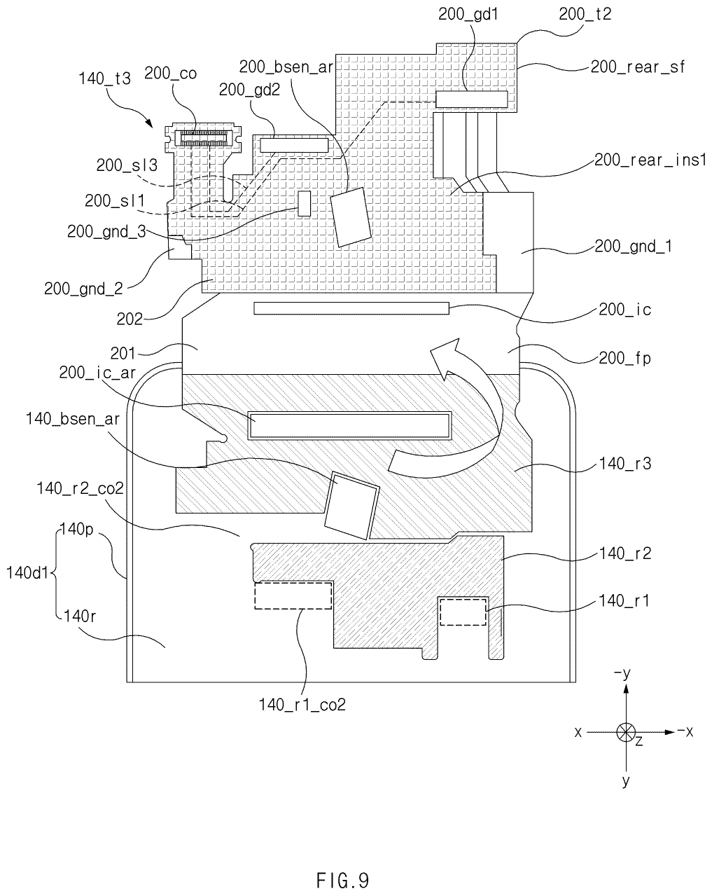

FIG. 9 is a diagram illustrating an example of a rear surface of an example display device according to various embodiments. The display device 140_t3 of FIG. 9 may be a modified example, in which at least a portion of the display device 140_t1 in

FIGS. 5 and 6 or the display device 140_t2 described in FIGS. 7 and 8 is modified.

Referring to FIGS. 1, 2, 3, 4, 5, 6, 7, 8 and 9, the display station 140_t3 according to an embodiment may include a display module 140d1 and an FPCB module 200_t2.

The display module 140d1 may include a panel part 140p and a rear part 140r. The panel part 140p may include a configuration that is the same as or similar to at least some of the components of the panel part 140p described above with reference to FIG. 4, 5, or 6. Accordingly, the description of the panel part 140p of FIG. 9 may be replaced with or supplemented with the description of the panel part described with reference to FIGS. 4, 5 and 6.

The rear part 140r may have a configuration that is the same as or similar to that of the rear part 140r described above with reference to FIG. 4, 5, or 6. As an example, the rear part 140r may include a plurality of layers including a metal layer. As described above in FIG. 4, the rear part 140r may include a first rear support layer 140_r1, a second rear support layer 140_r2, and a third rear support layer 140_r3.

The first rear support layer 140_r1 may include a metal layer (or a Cu layer). The first rear support layer 140_r1 may be disposed over an overall area (50% or more) of the rear surface of the display. The first rear support layer 140_r1 may be disposed in an area other than an area, in which the second rear support layer 140_r2 (or at least one of the second rear support layer 140_r2 and the third rear support layer 140_r3) is formed, among all areas of the rear surface of the display. The first rear support layer 140_r1 may be disposed in an area other than an area, in which the second rear support layer 140_r2 is disposed, and may be disposed to overlap the third rear support layer 140_r3 upward and downward with respect to the z-axis direction. The first rear support layer 140_r1 may support an overall area (e.g., 50% or more) of the panel part 140p. The first rear support layer 140_r1 may dissipate at least a portion of heat generated by the panel part 140p.

According to an embodiment, the first rear support layer 140_r1 included in the display device 140_t3 may include a first structure contact area 140_r1_co1 and a second structure contact area 140_r1_co2. At least a portion of the first structure contact area 140_r1_co1 may include an area that contacts the first guide structure 200_gd1 while the second type FPCB module 200_t2 is folded and at least a portion thereof is fixed to the rear part 140r. At least a portion of the second structure contact area 140_r1_co2 may include an area that contacts the second guide structure 200_gd2 while the second type FPCB module 200_t2 is folded and at least a portion thereof is fixed to the rear part 140r. The first structure contact area 140_r1_co1 and the second structure contact area 140_r1_co2 may not be divided into partial areas of the first rear support layer 140_r1, and may have a shape that is the same as or similar to that of the surroundings. According to various embodiments, the conductive adhesion member, in which the structure contact area described above in FIG. 7 is disposed, may be disposed in the first structure contact area 140_r1_co1 and the second structure contact area 140_r1_co2 (e.g., a metallic material area as a partial area of the first rear support layer 140_r1).

The second rear support layer 140_r2 and the third rear support layer 140_r3 may include a support layer having a shape that is the same as or similar to those of the second rear support layer 140_r2 and the third rear support layer 140_r3 described above with reference to FIG. 5 or FIG. 6. At least a portion of the second rear support layer 140_r2 and the third rear support layer 140_r3 may be modified. However, even when the second rear support layer 140_r2 and the third rear support layer 140_r3 are modified, the first guide structure 200_gd1 electrically contacts the first structure contact area 140_r1_co1, and the second guide structure 200_gd2 electrically contacts the second structure contact area 140_r1_co2, but it may be modified within a range, in which it is not interfered.

The rear part 140r may include a first area 140_bsen_ar, in which a biometric sensor is disposed, the same as or similar to the rear part 140r described above with reference to FIG. 5 or FIG. 6. While the FPCB module 200_t2 is folded and at least a portion thereof is fixed to the rear part 140r, the first area 140_bsen_ar may be aligned with the second area 200_bsen_ar formed in the second type FPCB module 200_t2.

The FPCB module 200_t2 may include the display FPCB 200_fp) (e.g., the first FPCB 200_fp1 divided in the x-axis direction described in FIG. 5) (or the display panel FPCB), the second FPCB 200_fp2 (or a touch panel FPCB) or the touch processor (e.g., the touch processor 140_tpic of FIG. 5), and the detection circuit (the detection circuit 301, 302, or 200_cir of FIG. 2 or 5). Furthermore, the FPCB module 200_t2 may include a first part 201 and a second part 202, similar to the first part and the second part described above in FIG. 6. According to an embodiment, the FPCB module 200_t2 may include a first guide structure 200_gd1, a first signal line 200_sl1, a second guide structure 200_gd2, and a third signal line 200_sl3 (or a second signal line in order). When the FPCB module 200_t2 includes a detection circuit (the detection circuit 200_cur of FIG. 6) connected to the first guide structure 200_gd1, as described above with reference to FIG. 6, it may include a first signal line 200_sl1 (e.g., the wiring line that connects the detection circuit 200_cir and the connector 200_co or the wiring line used to supply electric power to the detection circuit 200_cir) for an operation of the detection circuit (the detection circuit 200_cir of FIG. 6), and another wiring line that connects the second signal line (another wiring line that connects the detection circuit 200_cir and the connector 200_co, or a wiring line for detecting a signal change). According to an embodiment, the FPCB module 200_t2 may further include a detection circuit (e.g., other detection circuits for operating the first guide structure 200_gd1) for operating the second guide structure 200_gd2. As an example, the second type FPCB module 200_t2 may include a third signal line 200_sl3 (e.g., a wiring line that connects the detection circuit connected to the second guide structure 200_gd2 and a connector 200_co, or a wiring line used to supply electric power to the added detection circuit), and a fourth signal line (another wiring line that connects the detection circuit connected to the second guide structure 200_dg2 and the connector or a wiring line for detecting a signal change).

The FPCB module 200_t2 may further include a biometric sensor module. In relation to the disposition of the biometric sensor module, the display device 140_t3 may include a biometric sensor area 140_bsen_ar and 200_bsen_ar. The biometric sensor area 140_bsen_ar and 200_bsen_ar may include a first area, in which at least a part of the rear part 140r is removed and the rear surface of the panel part 140p (e.g., the rear surface of the display panel 140_pn in the −z-axis direction of FIG. 4 or 8) is exposed, and a second area 200_bsen_ar, from which a portion of the second part 202 of the second type FPCB module 200_t2 is removed. The biometric sensor area 140_bsen_ar and 200_bsen_ar may include an area, in which the first area 140_bsen_ar and the second area 200_bsen_ar overlap each other in the z-axis direction.

The FPCB module 200_t2 may include a first part 201 within the first distance (or that extends to the first distance from one periphery of the panel part 140p) from a periphery (e.g., the −y-axis periphery) of the panel part 140p, and a second part 202 within the second distance (that extends to the second distance from one periphery of the first part 201) from one periphery (e.g., the −y-axis periphery) of the first part 201 of the panel part 140p, and the first part 201 and the second part 202 may have partially different stack forms. For example, the number of first stacks of the first part 201 and the number of second stacks of the second part 201 may be different (or the number of the first stacks is smaller), or the flexibility of the first part 201 and the flexibility of the second part 202 may be different (or the flexibility of the first part 201 may be greater than that of the second part 202).

At least the first guide structure 200_gd1 and the second guide structure 200_gd2 spaced apart from each other, the first signal line 200_sl1, the third signal line 200_sl3, the connector 200_co, and at least one ground area 200_gd_1, 200_gd_2, and 200_gd_3 may be disposed in the second part 202 of the FPCB module 200_t2. The second part 202 may include at least a portion of a layer, on which wiring lines for driving a display panel (the display panel 140_pn of FIG. 4 or 8) are disposed, and at least a portion of a layer, on which wiring lines for driving a touch panel (the touch panel 140_tp of FIG. 8) are disposed. According to an embodiment, when the rear surface 200_rear_sf (the FPCB module 200_t2) of the FPCB module 200_t2 is folded and at least a portion thereof is fixed to the rear part 140r, the first and second guide structures 200_gd1 and 200_gd2 may be disposed so that at least a portion thereof is exposed to a surface that faces the rear part 140r of the display module 140d1. As an example, a portion of the metal layer, which is disposed on the rear surface 200_rear_sf of the second type FPCB module 200_t2, may define the first and second guide structures 200_gd1 and 200_gd2. According to an embodiment, the first guide structure 200_gd1 may be disposed at a first position of the rear surface 200_rear_sf of the second type FPCB module 200_t2, and the second guide structure 200_gd2 may be disposed at a second position (e.g., a position that is different from the first position) of the rear surface 200_rear_sf of the second type FPCB module 200_t2. According to embodiment, an FPCB rear surface insulating layer 200_rear_ins1 may be disposed on the rear surface 200_rear_sf of the second type FPCB module 200_t2. The first and second guide structures 200_gd1 and 200_gd2 may be exposed by removing the FPCB rear surface insulating layer 200_rear_ins1. The first and second guide structures 200_gd1 and 200_gd2 may be formed by applying a metallic material or disposing a metallic structure on the FPCB rear surface insulating layer 200_rear_ins1.

According to an embodiment, at least some layers of the first part 201 may be connected to at least some layers of the second part 202. As an example, when the first part 201 includes three layers and the second part 202 includes five layers, the three layers of the first part 201 may be connected to three layers of the second part 202. One of the remaining two layers of the second part 202 includes a first guide structure 200_gd1 and a second guide structure 200_gd2, a first signal line 200_sl1, a third signal line 200_sl3, and at least one ground area 200_gd_1, 200_gd_2, and 200_gd_3, and one of the remaining two layers may be formed such that the first guide structure 200_gd1, the second guide structure 200_gd2, and at least one ground area 200_gd_1, 200_gd_2, and 200_gd_3 are exposed, while covering at least a portion of the first metal. In the first metal layer, the first guide structure 200_gd1 and the first signal line 200_sl1 may be spaced apart (or isolated) from other metal patterns, the second guide structure 200_gd2 and the third signal line 200_sl3 may be spaced apart (or isolated) from other metal patterns, and at least one ground area 200_gd_1, 200_gd_2, and 200_gd_3 may be connected to each other.

The first signal line 200_sl1 may connect the connector 200_co to the first guide structure 200_gd1. The first signal line 200_sl1 may be used to supply electric power transmitted through the connector 200_co to the first guide structure 200_gd1, or may be used to sense a signal change caused by the first guide structure 200_gd1.

The third signal line 200_sl3 may connect the connector 200_co and the second guide structure 200_gd2. At least a portion of the third signal line 200_sl3 may be disposed in parallel with the first signal line 200_sl1. The third signal line 200_sl3 may be used to supply electric power transmitted through the connector 200_co to the second guide structure 200_gd2, or may be used to sense a signal change caused by the second guide structure 200_gd2. Among the components described in FIG. 9, the components that are the same as or similar to those described in FIG. 6 or FIG. 7 may be replaced or supplemented with the above-described contents.

In the display device 140_t3 according to the above-described embodiment, the second type FPCB module 200_t2 may include a plurality of guide structures. In the example embodiment described in relation to FIG. 9, a structure, in which two guide structures 200_gd1 and 200_gd2 are disposed, is illustrated, but the disclosure is not limited thereto, and the display device may further include three or more guide structures and signal lines that are connected to each of the guide structures. The display device 140_t3, in which a plurality of guide structures are disposed, may not only detect whether the second type FPCB module 200_t2 is folded to a preset distance in one direction (e.g., the y-axis direction) while the FPCB module 200_t2 is folded, and but also detect whether the second type FPCB module 200_t2 is abnormally inclined while being folded by identifying the contact state of each of the plurality of guide structures.

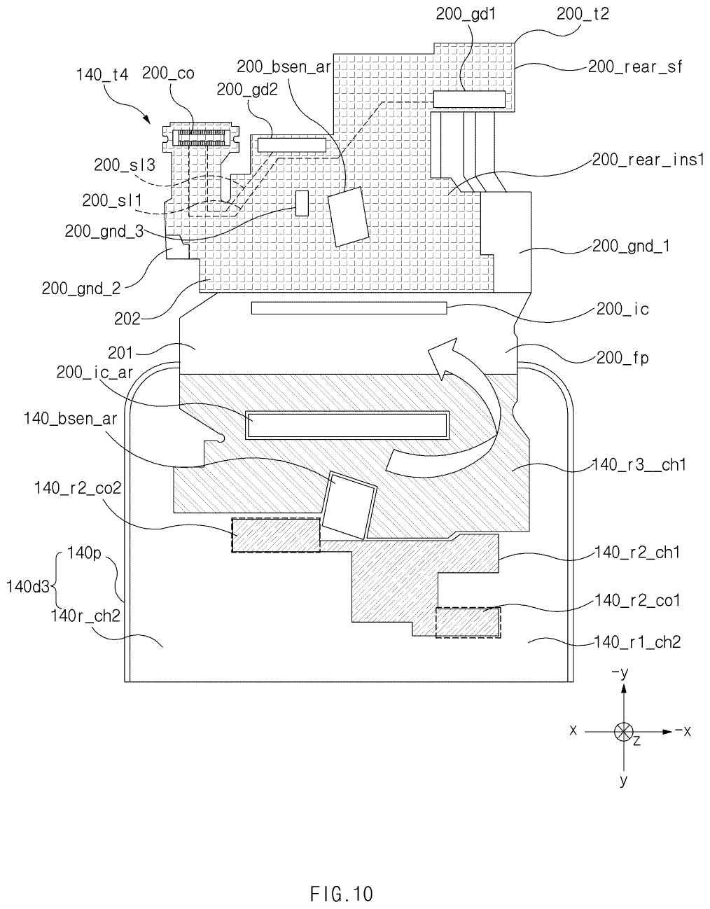

FIG. 10 is a diagram illustrating an example of a rear surface of an example display device according to various embodiments.

Referring to FIGS. 1, 2, 3, 4, 5, 6, 7, 8, 9 and 10, a display device 140_t4 according to an embodiment may include a second type FPCB module 200_t2 and a display module 140d3.

The second type FPCB module 200_t2 may have a configuration that is the same as or similar to that of the second type FPCB module described above with reference to FIG. 9. For example, the second type FPCB module 200_t2 includes a display FPCB 200_fp, and the display FPCB 200_fp may include the first part 201 and the second part 202 having different numbers of stacks. The second type FPCB module 200_t2 may include a configuration that is the same as or similar to that of the display FPCB 200_fp (e.g., the first FPCB (e.g., the first FPCB 200_fp1 of FIG. 5) (or the display panel FPCB) distinguished in the x-axis direction, the second FPCB (e.g., the first FPCB 200_fp1 of FIG. 5) (or a touch panel FPCB) or the touch processor (e.g., the touch processor 200_tpic of FIG. 5), and the detection circuit (the detection circuit 301, 302, or 200_cir of FIG. 2 or 5) described above in FIG. 5. According to an embodiment, the second type FPCB module 200_t2 may include the first guide structure 200_gd1, the first signal line 200_sl1, the second guide structure 200_gd2, the third signal line 200_sl3, the connector 200_co, and at least one ground area 200_gd_1, 200_gd_2, and 200_gd_3.

According to an embodiment, at least a portion of a layer, on which wiring lines for driving a display panel (e.g., the display panel 140_pn of FIG. 4 or 8) are disposed, and at least a portion of a layer, on which wiring lines for driving a touch panel (e.g., the touch panel 140_tp of FIG. 4 or 8) are disposed, may be disposed in the second part 202 of the second type FPCB module 200_t2. According to an embodiment, the first and second guide structures 200_gd1 and 200_gd2 may be disposed such that at least a portion thereof is exposed to the rear surface 200_rear_sf of the second type FPCB module 200_t2. When the second type FPCB module 200_t2 is folded and at least a portion thereof is fixed to the second modified rear part 140r_ch2 of the display module 140d3, the first and second guide structures 200_gd1 and 200_gd2 may contact the second modified rear part 140r_ch2 of the display module 140d3. As an example, an FPCB rear surface insulating layer 200_rear_ins1 may be disposed on the rear surface 200_rear_sf of the second type FPCB module 200_t2. The first and second guide structures 200_gd1 and 200_gd2 may be formed by removing and exposing the FPCB rear surface insulating layer 200_rear_ins1, or disposing a separate metal material or structure on the FPCB rear surface insulating layer 200_rear_ins1.

The second type FPCB module 200_t2 may further include a biometric sensor module. In relation to the disposition of the biometric sensor module, the display device 140_t4 may include a biometric sensor area 140_bsen_ar and 200_bsen_ar. The biometric sensor area 140_bsen_ar and 200_bsen_ar may include the first area 140_bsen_ar and the second area 200_bsen_ar described above.

According to an embodiment, at least some layers of the first part 201 may be connected to at least some layers of the second part 202. As an example, when the first part 201 includes five layers and the second part 202 includes seven layers, the five layers of the first part 201 may be connected to five layers of the second part 202. A metal layer of the remaining two layers of the second part 202 may include a metal pattern corresponding to a first guide structure 200_gd1 and a second guide structure 200_gd2, a first signal line 200_sl1, a third signal line 200_sl3, and at least one ground area 200_gd_1, 200_gd_2, and 200_gd_3. While the insulating layer of the remaining two layers of the second part 202 is formed to cover the specific metal layer above, at least a portion of the first guide structure 200_gd1 and the second guide structure 200_gd2, and at least one ground area 200_gd_1, 200_gd_2, and 200_gd_3 may be formed to be exposed, and the exposed portions (the first guide structure 200_gd1 and the second guide structure 200_gd2, and at least one ground area 200_gd_1, 200_gd_2, and 200_gd_3) may electrically contact a fourth modified rear support layer 140_r1_ch2 while the second type FPCB module 200_t2 is folded and fixed to the second modified rear part 140r_ch2 of the display module 140d3. Among the components of the display device described in FIG. 10, the components that are the same as or similar to those of the display devices described in FIG. 6 or FIG. 9 may be replaced or supplemented with the above-described contents.

The display module 140d3 may include a panel part 140p and a second modified rear part 140r_ch2. The panel part 140p may include the same configuration as at least some of the components of the panel part 140p described above with reference to FIG. 4.

As an example, the second modified rear part 140r_ch2 may include a plurality of layers including a metal layer. The second modified rear part 140r_ch2 may include a fourth modified rear support layer 140_r1_ch2, a second modified rear support layer 140_r2_ch1, and a third modified rear support layer 140_r3_ch1.

The fourth modified rear support layer 140_r1_ch2 may include a metal layer (or a Cu layer). The fourth modified rear support layer 140_r1_ch2 may be disposed over the entire display device rear surface. The fourth modified rear support layer 140_r1_ch2 may be disposed in an area other than an area, in which the second modified rear support layer 140_r2_ch1 (or at least one of the second modified rear support layer 140_r2_ch1 and the third modified rear support layer 140_r3_ch1) is formed, among the all the areas of the third modified rear support layer 140_r3_ch1. The fourth modified rear support layer 140_r1_ch2 may be disposed in an area other than the area, in which the second modified rear support layer 140_r2_ch1 is formed, and may be disposed to overlap the third modified rear support layer 140_r3_ch1 in the upward/downward direction with respect to the z-axis direction. The fourth modified rear support layer 140_r1_ch2 may support the overall panel part 140p. The fourth modified rear support layer 140_r1_ch2 may radiate at least a portion of heat generated in the panel part 140p.

At least a portion of the fourth modified rear support layer 140_r2_ch1 may be removed and exposed to the second modified rear support layer 140_r1_ch2.

The second modified rear support layer 140_r2_ch1 may be disposed between the panel part 140p and the fourth modified rear support layer 140_r1_ch2 with respect to the z-axis direction. The second modified rear support layer 140_r2_ch1 may be disposed between the third modified rear support layer 140_r3_ch1 and a lower end portion of the fourth modified rear support layer 140_r1_ch2 with respect to the y-axis direction. At least a portion of the second modified rear support layer 140_r2_ch1 may include portions that contact the first guide structure 200_gd1 and the second guide structure 200_gd2 disposed in the second type FPCB module 200_t2. As an example, while the second type FPCB module 200_t2 is folded and at least a portion thereof is fixed to the second modified rear part 140r_ch2, the second modified rear support layer 140_r_ch1 may include a third structure contact area 140_r2_co1 that faces (or contacts) the first guide structure 200_gd1 and a fourth structure contact area 140_r2_co2 that faces (or contacts) the second guide structure 200_gd2. According to an embodiment, an adhesive material may be applied or an adhesion member may be disposed on the second modified rear support layer 140_r2_ch1. The second modified rear support layer 140_r2_ch1 may serve as an impact absorbing layer. The second modified rear support layer 140_r2_ch1 may be formed of a nonconductive material. As an example, at least a portion of the second modified rear support layer 140_r2_ch1 may be formed of sponge or a plurality of embosses of a nonconductive material. Correspondingly, the third structure contact area 140_r2_co1 and the fourth structure contact area 140_r2_co2 may include a nonconductive area. Even when the first guide structure 200_gd1 and the third structure contact area 140_r2_co1 physically contact each other, they may not electrically contact each other. Even when the second guide structure 200_gd2 and the fourth structure contact area 140_r2_co2 physically contact each other, they may not electrically contact each other.

The third modified rear support layer 140_r3_ch1 may include an adhesion layer that is separately adhered onto the fourth modified rear support layer 140_r1_ch2. At least a portion of the third modified rear support layer 140_r3_ch1 may include a shape corresponding to a shape of at least a portion of the shape of the rear surface of the second type FPCB module 200_t2. The third modified rear support layer 140_r3_ch1 may include a conductive adhesion member. The third modified rear support layer 140_r3_ch1 may fix at least a portion of the second type FPCB module 200_t2 to the second modified rear part 140r_ch2. While the second type FPCB module 200_t2 is folded, a partial area of the third modified rear support layer 140_r3_ch1 corresponding to an area, in which the display processor 200_ic is disposed, may be removed. While the second type FPCB module 200_t2 is folded, an area of the third modified rear support layer 140_r3_ch1 and the fourth modified rear support layer 140_r1_ch1 corresponding to an area, in which the display processor 200_ic is disposed, is removed to become an area, in which the second modified rear support layer 140_r2_ch1 is exposed. The third modified rear support layer 140_r3_ch1 may be disposed at a first distance from a periphery (e.g., a −y-axis periphery) of one side of the panel part 140p (or the display panel 140_pn of FIG. 4), and the second modified rear support layer 140_r2_ch1 may be disposed at a second distance (e.g., a distance that is greater than the first distance) from a periphery (e.g., a −y-axis periphery) of one side of the panel part 140p (or the display panel 140_pn).

The second modified rear part 140r_ch2 may include a first area 140_bsen_ar, in which a biometric sensor is disposed. The first area 140_bsen_ar may be formed to pass through the fourth modified rear support layer 140_r1_ch2, the second modified rear support layer 140_r2_ch1, and the third modified rear support layer 140_r3_ch1 in the z-axis direction. When the second type FPCB module 200_t2 is in a folded state, the first area 140_bsen_ar may be aligned with the second area 200_bsen_ar formed in the second type FPCB module 200_t2.

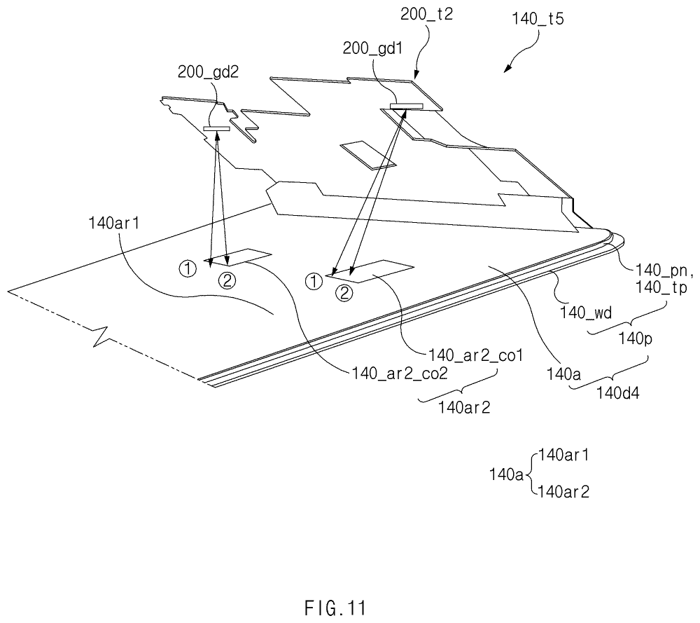

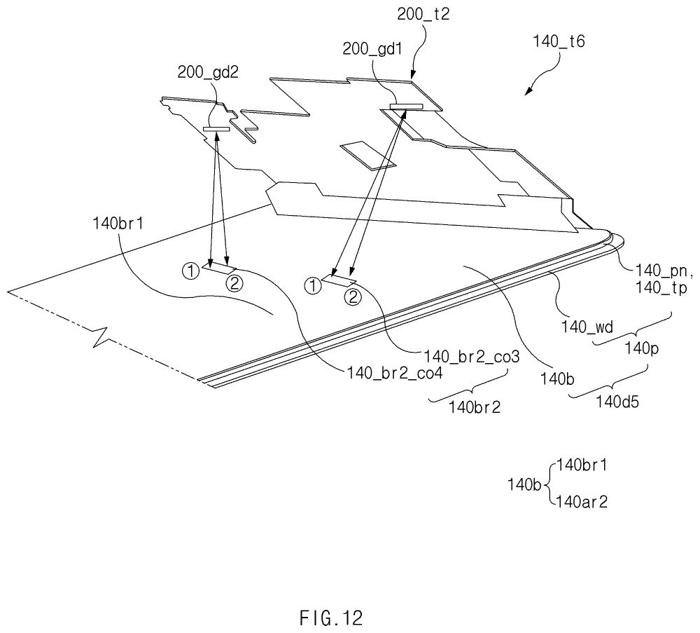

The display device 140_t4 according to the above-described embodiment may include a plurality of guide structures 200_gd1 and 200_gd2 in the second type FPCB module 200_t2, and may include a structure, in which a plurality of guide structures 200_gd1 and 200_gd2 contact the second modified rear support layer 140_r2_ch1 corresponding to the nonconductive area of the display module 140d3 while the second type FPCB module 200_t2 is folded. The inspection jig or the main processor is connected to the connector 200_co, and when a signal value corresponding to a floating state is detected by the plurality of guide structures 200_gd1 and 200_gd2, it may be determined as being normal. In this regard, it will be described in greater detail with reference to FIGS. 11 and 12.

FIG. 11 is a perspective view illustrating an example of a display device, in which a second type FPCB module is folded, according to various embodiments. FIG. 11 illustrates a simplified display device for describing a technology for determining a normality or a defect according to a signal detected from a contact state between the guide structures 200_gd1 and 200_gd2 and the rear part 140a. As an example, the display device 140_15 of FIG. 11 may be replaced with at least one of the display devices illustrated in FIG. 2, 3, 4, 5, 6, 7, 8, 9 or 10 (which may be referred to as FIGS. 1 to 10), and correspondingly, the normality or defective state determination technology described in FIG. 11 may be applied equally or similarly.

Referring to FIGS. 1, 2, 3, 4, 5, 6, 7, 8, 9, 10 and 11, a display device 140_t5 according to an embodiment may include a second type FPCB module 200_t2 and a display module 140d4.

The display module 140d4 may include a panel part 140p and a rear part 140a. The panel part 140p may include at least a touch panel 140_tp (e.g., the touch panel 140_tp of FIG. 4 or 8), a display panel 140_pn (e.g., the display panel 140_pn of FIG. 4 or 8), and a window 140_wd (e.g., the window 140_wd of FIG. 4 or 8). The rear part 140a may include, for example, a first rear support layer 140ar1 and a second rear support layer 140ar2. The rear part 140a may further include the above-described third rear support layer (e.g., the third rear surface support layer 140_r3 of FIG. 6) (or a third modified rear support layer of another drawing). Furthermore, at least a portion of the second rear support layer 140ar2 may have a structure that is the same as or similar to that of at least a portion of the second rear support layer 140_r2 or the second modified rear support layer 140_r2_ch1 described in other drawings.

The first rear support layer 140ar1 may include a part (or a structure) formed of a metallic material. The first rear support layer 140ar1 may contact at least a portion of one surface of the second type FPCB module 200_t2 while the second type FPCB module 200_t2 is folded. The first rear support layer 140ar1 may have a structure that is the same as or similar to that of at least a portion of the first rear support layer, the first modified rear support layer, or the fourth modified rear support layer described above with reference to FIGS. 1 to 10.

The second rear support layer 140ar2 may be formed by removing a portion of the first rear support layer 140ar1. For example, the second rear support layer 140ar2 may include a first detection area 140_ar2_co1 and a second detection area 140_ar2_co2. The first and second detection areas 140_ar2_co1 and 140_ar2_co2 may correspond to the structure contact areas described above. As the second rear support layer 140ar2 is formed of a nonconductive material, the first and second detection areas 140_ar2_co1 and 140_ar2_co2 may include a nonconductive area.

In the display device 140_t5 (or a portable communication device) including the second type FPCB module 200_t2 and the display module 140d4, the positions of the first guide structure 200_gd1 and the second guide structure 200_gd2 may be designed such that a state, in which it contacts one area or one position (e.g., the first position) of the first rear support layer 140ar1, is a normal state. Accordingly, when the signal detected from the first guide structure 200_gd1 and the second guide structure 200_gd2 is a signal corresponding to a floating state, the main processor or the inspection jig of the portable communication device may determine that the first and second guide structures 200_gd1 and 200_gd2 contact a position (e.g., the second position) corresponding to the first and second detection areas 140_ar2_co1 and 140_ar2_co2, respectively, determine that the display device 140_t5 is in a defective state, and output a result thereof. When the signal detected from the first guide structure 200_gd1 and the second guide structure 200_gd2 is a signal corresponding to the ground state, the main processor or the inspection jig of the portable communication device may determine that the first and second guide structures 200_gd1 and 200_gd2 contact one area or one position (e.g., the first position) of the first rear support layer 140ar1, respectively, determine that the portable communication device (or the display device 140_t5) is in a normal state, and output the result thereof.

FIG. 12 is a perspective view illustrating an example of a display device, in which a second type FPCB module is folded, according to various embodiments. FIG. 12 illustrates a simplified display device for describing a technology for determining a normality or a defective state according to a signal detected from a contact state between the guide structures 200_gd1 and 200_gd2 and the rear part 140b, and the display device 140_t6 of FIG. 12 may be replaced with at least one of the display devices illustrated in FIG. 2, 3, 4, 5, 6, 7, 8, 9 or 10 (which may be referred to as FIGS. 2 to 10). Correspondingly, the normality or defective state determination technology described in FIG. 12 may be applied equally or similarly to at least one of the display devices described in FIGS. 2 to 10.

Referring to FIGS. 1, 2, 3, 4, 5, 6, 7, 8, 9, 10, 11 and 12, a display device 140_t6 according to an embodiment may include a second type FPCB module 200_t2 and a display module 140d5.

The display module 140d5 may include a panel part 140p and a rear part 140b. The panel part 140p may include at least a touch panel 140_tp (e.g., the touch panel 140_tp of FIG. 4 or 8), a display panel 140_pn (e.g., the display panel 140_pn of FIG. 4 or 8), and a window 140_wd (e.g., the window 140_wd of FIG. 4 or 8). Furthermore, the panel part 140p may further include other components described above, for example, a polarizing plate or an adhesion layer.

The rear part 140b may include, for example, a first rear support layer 140br1 and a second rear support layer 140br2. The rear part 140b may further include the third rear support layer (or the third modified rear support layer) described above. At least a portion of the second rear support layer 140br2 may have a structure that is the same as or similar to that of at least a portion of the second rear support layer 140_r2 or the second modified rear support layer 140_r2_ch1 described above.

At least a portion or the whole of the first rear support layer 140br1 may be formed of a metallic material. The first rear support layer 140br1 may contact at least a portion of one surface of the second type FPCB module 200_t2 while the second type FPCB module 200_t2 is folded. The first rear support layer 140br1 may have a structure that is the same as or similar to that of at least a portion of the first rear support layer, the first modified rear support layer, or the fourth modified rear support layer described above with reference to FIGS. 1 to 10. The first rear support layer 140br1 may partially vary depending on a change in the size of a portion, at which the second rear support layer 140br2 is exposed.

The second rear support layer 140br2 may be formed by removing a portion of the first rear support layer 140br1. For example, the second rear support layer 140br2 may include a third detection area 140_br2_co3 and a fourth detection area 140_br2_co4. The third and fourth detection areas 140_br2_co3 and 140_br2_co4 may have different positions and sizes from those of the first and second detection areas 140_ar2_co1 and 140_ar2_co2 described above with reference to FIG. 11. As the second rear support layer 140br2 is formed of a nonconductive material, the third and fourth detection areas 140_br2_co3 and 140_br2_co4 may include a nonconductive area.

In the portable communication device (or the display device 140_t6) including the second type FPCB module 200_t2 and the display module 140_t5 illustrated in FIG. 12, the positions of the first guide structure 200_gd1 and the second guide structure 200_gd2 become abnormal when they contact an area or a position (e.g., the first position) of the first rear support layer 140br1, and they may be designed such that a state, in which they contact the position (e.g., the second position) corresponding to the third and fourth detection areas 140_br2_co3 and 140_br2_co4, is a normal state. According to an embodiment, in the display device 140_t6 (or portable communication device), when the second type FPCB 200_t2 is folded such that the first guide structure 200_gd1 and the second guide structure 200_gd2 contact a position (e.g., the second position) corresponding to the third and fourth detection areas 140_br2_co3 and 140_br2_co4, respectively, the main processor or the inspection jig of portable communication device may determine a normal state (e.g., a state, in which the separation distance between the folded part of the second type FPCB module 200_t2 and the housing antenna has a pre-designed distance) when a signal depending on the floating state from the first guide structure 200_gd1 and the second guide structure 200_gd2 is detected. When determining the normal state, the inspection jig or the main processor of the portable communication device may output a signal (or information, a text, or an image) corresponding thereto to a specific display or a display panel of the portable communication device. When the signal detected from the first guide structure 200_gd1 and the second guide structure 200_gd2 is a signal corresponding to the ground state, the main processor or the inspection jig of the portable communication device may determine that the guide structures 200_gd1 and 200_gd2 contact one area or one position (e.g., the first position) of the first rear support layer 140_br1, respectively, determine that the display device 140_t6 is in an abnormal state, and output the result thereof.

In the above description, it has been described that the first rear support layer 140br1 is disposed on an outermost layer in the −z-axis direction, and the second rear support layer 140br2 is disposed under the first rear support layer 140br1 with respect to a direction (or a direction from the rear surface of the portable communication device to the front surface of the display) from the −z-axis to the z-axis, but the portable communication device of the disclosure is not limited to this. For example, the first rear support layer 140br1 of a metallic material may be disposed under the second rear support layer 140br2 of a nonconductive material with respect to the direction from the −z-axis toward the z-axis above. In such a structure, the display module may be configured such that at least a portion of the second rear support layer 140br2 is removed and at least a portion of the first rear support layer 140br1 is exposed in the −z-axis direction, and the exposure position and size of the first rear support layer 140br1 may vary depending on whether the contact state with at least one guide structure is determined as being normal or the non-contact state is determined as being normal.

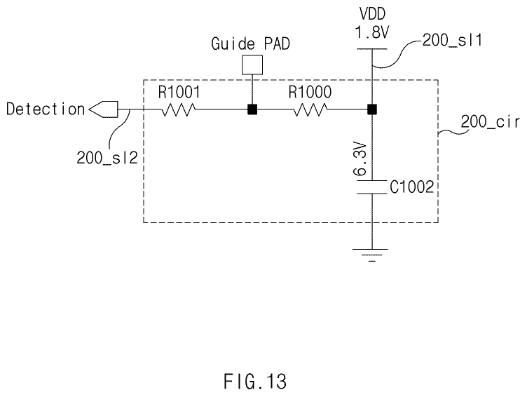

FIG. 13 is a circuit diagram illustrating an example of at least a portion of a detection circuit according to various embodiments.

Referring to FIGS. 1, 2, 3, 4, 5, 6, 7, 8, 9, 10, 11, 12 and 13, in the above description of the portable electronic device of the disclosure related to FIG. 2, the detection circuit 200_cir may be disposed in a specific part of the display FPCB module 200, a specific part of the printed circuit board, or a specific part of the inspection jig. In this way, the detection circuit 200_cir for detecting an electrical state of the guide structure (or guide structures) of the disclosure may be disposed in the portable communication device (or the display device) or a separate inspection jig. When the detection circuit 200_cir is disposed in the inspection jig, the display FPCB module 200 of the disclosure may include only the signal line that connects the connector 200_co and the guide structure (or guide structures) (e.g., 200sl1 and 200sl3 of FIGS. 7 to 10), and may not include the detection circuit 200 cir illustrated in FIG. 13.

The detection circuit 200_cir may include a first capacitor C1002 and distribution resistors R1001 and R1000. The detection circuit 200_cir may be electrically connected to a first signal line 200_sl1 (e.g., the first signal line 200_sl1 described in FIG. 5 or 6) that is used to supply a designated voltage (e.g., 1.8v, VDD). The VDD is a component for supplying electric power to the detection circuit 200_cir, and may correspond to a part (or some terminals) of a power supply part of the inspection jig or a power supply part (or a processor that controls the power supply part) of the portable communication device. The guide structure PAD may include at least one of the first guide structure 200_gd1 and the second guide structure 200_gd2 described with reference to FIGS. 1, 2, 3, 4, 5, 6, 7, 8, 9, 10, 11 and 12. The guide structure (guide pad) may be disposed between a first distribution resistor R1000 and a second distribution resistor R1001. The detection end may be connected to one side (e.g., one end of the second distribution resistor R1001) of the detection circuit 200_cir through the second signal line 200_sl2. The detection end may be included, for example, at one end of a processor (e.g., an inspection jig or a main processor of a portable communication device) connected to the connector 200_co. The processor may determine whether the disposition state of the FPCB module of the display device is disposed in a set state (e.g., a normal state) or is disposed differently from the set state (e.g., an abnormal state) based on a signal change detected through the detection end.

In this process, a normality or abnormality may be differently determined depending on the pre-designed value. For example, while the display FPCB module is folded, a state, in which a value (or 1.8V or a preset specific reference value or higher) corresponding to the floating state of a signal transmitted from the guide structure (or guide structures) is detected, may be designed to be in a normal state. While the display FPCB module is folded, a state, in which a value (or 0V or a GND value) corresponding to the ground state of a signal transmitted from the guide structure (or guide structures) is detected, may be designed to be a normal state. The main processor or the inspection jig of the portable communication device may compare a signal transmitted from the guide structure (or guide structures) with a value set to a specific normal value to determine whether the display device (or portable communication device) is in a normal state and output a result thereof.

According to various embodiments, the detection circuit described in FIG. 13 may be applied to one first guide structure 200_gd1 described above, or when there are a plurality of first guide structures 200_gd1 and a plurality of second guide structures 200_gd2 as illustrated in FIG. 9 or FIG. 10, the detection circuit of FIG. 13 may be applied to each of the plurality of guide structures in the same manner. The portable communication device may be configured to include one detection circuit, a plurality of guide structures, and a plurality of signal lines that connect the plurality of guide structures and one detection circuit.

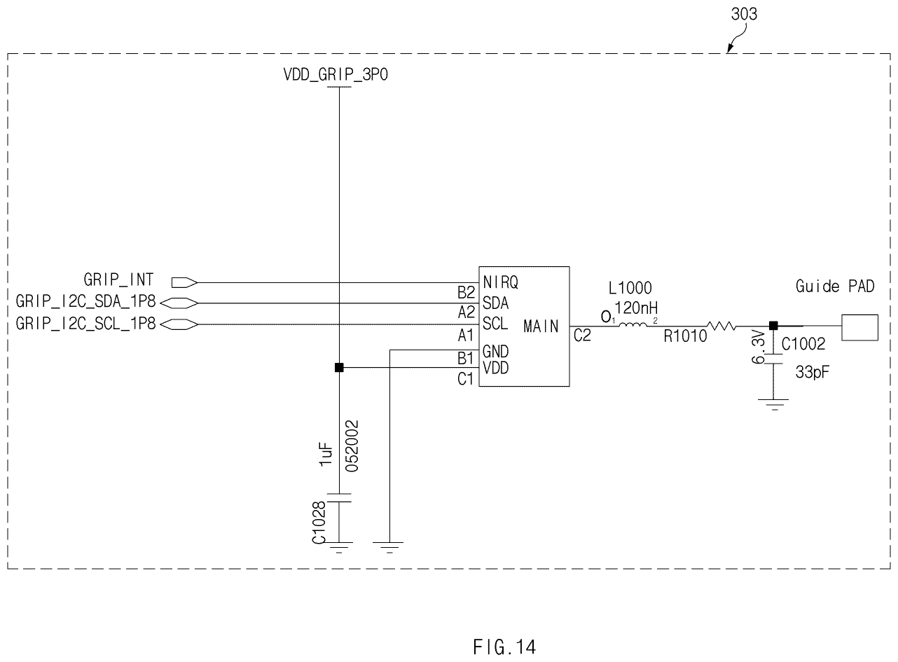

FIG. 14 is a circuit diagram illustrating an example of a circuit for determining a normal state using detection of a capacitance according to various embodiments.

Referring to FIG. 14, the portable communication device or inspection jig of the disclosure may detect a change in the capacitance transmitted by the guide structure (guide pad), and determine whether the display device is normal or abnormal through the detected change in the capacitance. In this regard, the portable communication device or the inspection jig may electrically connect the capacitance sensing sensor 303 (or a grip sensor) included in the portable communication device to the guide structure (a guide pad) and detect a change in the capacitance of the guide structure (the guide pad).

As an example, the portable communication device or inspection jig may determine that the state is a normal (or abnormal) state when a change in the capacitance detected from the guide structure (guide pad) is less than a preset value while the display FPCB module is folded, and may determine that the state is an abnormal (or normal) state when it is the preset value or more. The normal or abnormal state may be designed differently depending on, which of the guide structure (guide pad) and the rear part of the display module is disposed to contact or the spacing distance or a contact between the first rear support layer 140_r1 or the second rear support layer 140_r2 and the guide structure (guide pad).

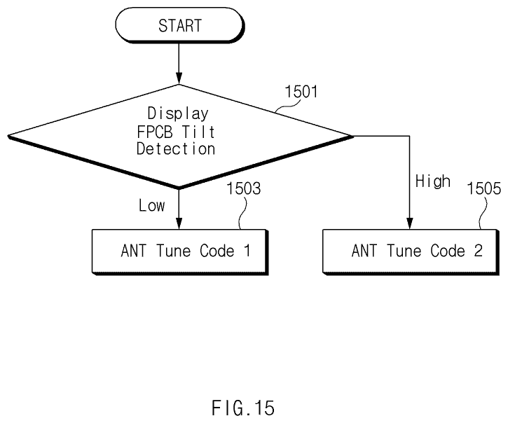

FIG. 15 is a flowchart illustrating an example antenna tuning method of a portable communication device according to various embodiments. In this regard, the portable communication device (device 100 of FIG. 1 or 2) may include a main processor (or a communication processor or a communication circuit), a tunable antenna (or a tunable antenna or a tunable antenna connected to a housing antenna), a display device (e.g., the display FPCB module and the display module described in FIGS. 2 to 12), a guide structure (e.g., at least one guide structure 200_gd1 and 200_gd2 described in FIGS. 2 to 12) disposed in the display FPCB module, and may include a signal line (or a plurality of signal lines that connect the detection circuit connected to the at least one guide structure and the connector) that connects the at least one guide structure and the connector disposed in the display FPCB module. The portable communication device 100 may identify a signal value of a specific terminal (a terminal, to which a signal line electrically connected to the guide structure is connected) of the connector disposed on the display FPCB module, and may identify a position of the guide structure that contacts the rear part of the display module based on the corresponding signal value. According to an embodiment, the main processor of the portable communication device 100 may detect a change in the capacitance between the housing antenna (e.g., the housing antenna 188_at1 or 188_at2 of FIG. 3) and the display FPCB module, calculate a tuning value of the antenna depending on the change value, and apply the calculated tuning value of the antenna to improve radiation deviation.

For example, referring to FIG. 15, the portable communication device (e.g., the main processor of the portable communication device 100 of FIG. 1) may detect a capacitance value (display FPCB tilt detection) depending on the distance between the guide structure and the rear part of the display module in operation 1501.

The portable communication device (the device 100 of FIG. 1 or 2) may identify the capacitance value with a lookup table that is stored in the memory (memory 120 of FIG. 1) in advance and apply the tuning value according to the identified value to the tunable antenna. For example, in the portable communication device (the device 100 of FIG. 1 or 2), when the capacitance value (display FPCB tilt detection) is a “low” value, in operation 1503, a first antenna tune code value (Ant Tune Code 1) may be applied to the tunable antenna. In the portable communication device (the device 100 of FIG. 1 or 2), when the capacitance value (display FPCB tilt detection) is a “high” value, in operation 1505, the second antenna tune code value (Ant Tune Code 2) may be applied to the tunable antenna.

As described above, the portable communication device (the device 100 of FIG. 1 or 2) according to an embodiment may adjust the movement of the resonance frequency corresponding to the radiation deviation depending on the distance deviation between the housing antenna and the display FPCB module (or the display device or the chip on plastic or panel (COP)) due to the assembly deviation of the display FPCB module. As a result, the portable communication device (the device 100 of FIG. 1 or 2) according to an embodiment may address the radiation deviation according to the operation of the communication circuit of the portable communication device (the device 100 of FIG. 1 or 2) by moving the resonance frequency through tuning.

As described above, the display device included in the portable electronic device according to an example embodiment of the disclosure includes: a panel part including a display panel, in which a plurality of pixels are disposed, a display module including a rear part including a support that supports the panel part, and a display flexible printed circuit board (FPCB) module connected to the display module, wherein the display FPCB module includes a guide structure including a guide disposed at the first position of the rear surface of the display FPCB module and configured to contact a portion of the rear part based on being folded, a signal line connected to the guide structure, and a connector connected to the signal line.

According to an example embodiment, in the display device, the rear part may include a first rear support layer, at least a portion of which includes a metallic material, and a second rear support layer, at least a portion of which includes a nonmetallic material, and a first structure contact area defined by a portion of the first rear support layer, and at least a portion of which is surrounded by the second rear support layer, wherein the first position may correspond to a position, at which the guide structure contacts the first structure contact area, while the display FPCB is folded.

According to an example embodiment, in the display device, the rear part may include a first rear support layer, at least a portion of which includes a metallic material, and a second rear support layer, at least a portion of which includes a nonmetallic material, and a structure adhesion area disposed at a portion of the first rear support layer, and in which a conductive adhesion member comprising a conductive adhesive is disposed, and the first position may correspond to a position, at which the guide structure contacts the structure contact area, while the display FPCB is folded.

According to an example embodiment, the display device may further include a detection circuit connected to the guide structure, and the signal line may include a first signal line configured to supply electric power to the detection circuit, and a second signal line configured to sense a change in a state of the detection circuit.

According to an example embodiment, in the display device, the display FPCB module may include a plurality of metal pattern layers and a plurality of insulating layers, the guide structure and the first signal line may be disposed on, among the plurality of metal pattern layers, a first metal pattern layer, the first signal line may be covered by, among the plurality of insulating layers, a first insulating layer, and the guide structure may be located at a portion, at which a portion of the first insulating layer is removed.

According to an example embodiment, in the display device, the display FPCB module may include a plurality of metal pattern layers and a plurality of insulating layers, among the plurality of metal pattern layers, a first metal pattern layer may include ground terminals, and the guide structure and the first signal line (or the first signal line and the second signal line) may be formed to be spaced apart from the ground terminals while being disposed on the first metal pattern layer.

According to an example embodiment, in the display device, the guide structure may include a first guide structure including a guide disposed at the first position, and a second guide structure including a guide disposed at a second position being different from the first position.

According to an example embodiment, in the display device, the signal line may include a first signal line connecting the connector and the first guide structure, and a second signal line (e.g., the signal line 200_sl3 of FIG. 9) connecting the connector and the second guide structure.

According to an example embodiment, in the display device, the display FPCB module may include a plurality of metal pattern layers and a plurality of insulating layers, the first guide structure, the second guide structure, the first signal line, and the second signal line (e.g., the signal line 200_sl3 of FIG. 9) may be disposed on, among the plurality of metal pattern layers, a first metal pattern layer, the first signal line and the second signal line (e.g., the signal line 200_sl3 of FIG. 9) may be covered by, among the plurality of insulating layers, a first insulating layer, and the first guide structure and the second guide structure may be located at portions, at which a portion of the first insulating layer is removed.

According to an example embodiment, in the display device, the rear part may include a first rear support layer, at least a portion of which includes a metallic material, and a second rear support layer, at least a portion of which includes a nonmetallic material, and the first rear support layer may include the first structure contact area which the first guide structure is configured to contact while the display FPCB module is folded, and the second structure contact area which the second guide structure is configured to contact.

According to an example embodiment, in the display device, the rear part may include a first rear support layer, at least a portion of which includes a metallic material, and a second rear support layer, at least a portion of which includes a nonmetallic material, and the second rear support layer may include the third structure contact area which the first guide structure is configured to contact while the display FPCB module is folded, and the fourth structure contact area which the second guide structure is configured to contact.

A portable communication device according to an example embodiment of the disclosure may include: a display device, and a housing, on which the display device is positioned, at least a portion of which includes a metallic material, and having a side wall configured to be used as an antenna, the display device may include a display module including a panel part (including a display panel), in which a plurality of pixels are disposed, and a rear part (including a support) supporting the panel part, and a display flexible printed circuit board (FPCB) module including an FPCB connected to the display module, and including a folding area located within a specified distance at the side wall while being positioned on the housing, and the display FPCB module may include a guide structure including a guide disposed at a first position of a rear surface of the display FPCB module and configured to contact a portion of the rear part based on being folded, a signal line connected to the guide structure, and a connector connected to the signal line.

According to an example embodiment, in the portable communication device, the rear part may include a first rear support layer, at least a portion of which includes a metallic material, and a second rear support layer, at least a portion of which includes a nonmetallic material, and a first structure contact area defined by a portion of the first rear support layer, and at least a portion of which is surrounded by the second rear support layer, and the first position may correspond to a position, at which the guide structure contacts the first structure contact area, while the display FPCB is folded.

According to an example embodiment, in the portable communication device, the rear part may include a first rear support layer, at least a portion of which includes a metallic material, and a second rear support layer, at least a portion of which includes a nonmetallic material, and a structure adhesion area disposed at a portion of the first rear support layer, and in which a conductive adhesion member comprising a conductive adhesive is disposed, and the first position may correspond to a position, at which the guide structure contacts the structure contact area, while the display FPCB is folded.

According to an example embodiment, the portable communication device may further include: a detection circuit connected to the guide structure, and the signal line may include a first signal line configured to supply electric power to the detection circuit, and a second signal line configured to sense a change in a state of the detection circuit, the display FPCB module may include a plurality of metal pattern layers and a plurality of insulating layers, among the plurality of metal pattern layers, a first metal pattern layer may include at least one ground terminal, the guide structure, the first signal line, and the second signal line, the first signal line and the second signal line may be covered by, among the plurality of insulating layers, a first insulating layer, and the guide structure and the ground terminal may be located at a portion in which the first insulating layer is removed.

According to an example embodiment, in the portable communication device, the guide structure may include a first guide structure comprising a guide disposed at the first position, and a second guide structure comprising a guide disposed at a second position different from the first position, and the signal line may include a first signal line connecting the connector and the first guide structure, and a second signal line (e.g., the signal line 200_sl3 of FIG. 9) connecting the connector and the second guide structure.

According to an example embodiment, in the portable communication device, the rear part may include a first rear support layer, at least a portion of which includes a metallic material, and a second rear support layer, at least a portion of which includes a nonmetallic material, and the first rear support layer may include the first structure contact area which the first guide structure is configured to contact while the display FPCB module is folded, and the second structure contact area which the second guide structure is configured to contact.

According to an example embodiment, the portable communication device may further include at least one processor, comprising processing circuitry, connected to the connector, wherein at least one processor, individually and/or collectively, may be configured to: determine that the display FPCB module is in a normal state based on the first guide structure and the second guide structure being grounded, and output information corresponding to the normal state.

According to an example embodiment, in the portable communication device, the rear part may include a first rear support layer, at least a portion of which includes a metallic material, and a second rear support layer, at least a portion of which includes a nonmetallic material, and the second rear support layer may include the third structure contact area which the first guide structure is configured to contact while the display FPCB module is folded, and the fourth structure contact area which the second guide structure is configured to contact.

According to an example embodiment, the portable communication device may further include: at least one processor, comprising processing circuitry, connected to the connector, wherein at least one processor, individually and/or collectively, may be configured to: determine that the display FPCB module is in a normal state based on the first guide structure and the second guide structure being floated, and output information corresponding to the normal state.

According to an example embodiment, the portable communication device may further include: at least one processor, comprising processing circuitry, connected to the connector, a housing, at least a portion of which is configured as an antenna, and in which the processor is disposed in an interior thereof, and a tunable antenna electrically connected to a portion of the housing, wherein at least one processor, individually and/or collectively, may be configured to: detect a change in a capacitance between the portion of the housing used as the antenna and the display FPCB module, calculate an antenna tuning value depending on the change in the capacitance, and apply the calculated antenna tuning value to the tunable antenna.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A display device comprising:
a display module including a panel part comprising a display panel, in which a plurality of pixels are disposed, and a rear part including a support supporting the panel part; and
a display flexible printed circuit board (FPCB) module including an FPCB connected to the display module,
wherein the display FPCB module includes:
a guide structure including a guide disposed at a first position of a rear surface of the display FPCB module and configured to contact a portion of the rear part of the display module based on the display FPCB module being in a folded state;
a signal line connected to the guide structure; and
a connector connected to the signal line.

2. The display device of claim 1, wherein the rear part includes:
a first rear support layer, at least a portion of which includes a metallic material;
a second rear support layer, at least a portion of which includes a nonmetallic material; and
a first structure contact area defined by a portion of the first rear support layer, and at least a portion of which is surrounded by the second rear support layer, and
wherein the first position corresponds to a position, at which the guide structure contacts the first structure contact area, while the display FPCB is folded.

3. The display device of claim 1, wherein the rear part includes:
a first rear support layer, at least a portion of which includes a metallic material;
a second rear support layer, at least a portion of which includes a nonmetallic material; and
a structure adhesion area disposed at a portion of the first rear support layer, and in which a conductive adhesion member comprising a conductive adhesive is disposed, and
wherein the first position corresponds to a position, at which the guide structure contacts a structure contact area, while the display FPCB is folded.

4. The display device of claim 1, further comprising:
a detection circuit connected to the guide structure,
wherein the signal line includes:
a first signal line configured to supply electric power to the detection circuit; and
a second signal line configured to sense a change in a state of the detection circuit.

5. The display device of claim 1, wherein the display FPCB module includes:
a plurality of metal pattern layers and a plurality of insulating layers,
wherein the guide structure and the signal line are disposed on a first metal pattern layer among the plurality of metal pattern layers,
wherein the first signal line is covered by a first insulating layer among the plurality of insulating layers, and
wherein the guide structure is located at a position at which a portion of the first insulating layer is removed.

6. The display device of claim 1, wherein the display FPCB module includes:
a plurality of metal pattern layers and a plurality of insulating layers,
wherein, among the plurality of metal pattern layers, a first metal pattern layer includes ground terminals, and
wherein the guide structure and the signal line are spaced apart from the ground terminals and disposed on the first metal pattern layer.

7. The display device of claim 1, wherein the guide structure includes:
a first guide structure including a guide disposed at the first position; and
a second guide structure including a guide disposed at a second position different from the first position.

8. The display device of claim 7, wherein the signal line includes:
a first signal line connecting the connector and the first guide structure; and
a second signal line connecting the connector and the second guide structure.

9. The display device of claim 8, wherein the display FPCB module includes:
a plurality of metal pattern layers and a plurality of insulating layers,
wherein the first guide structure, the second guide structure, the first signal line, and the second signal line are disposed on a first metal pattern layer among the plurality of metal pattern layers,
wherein the first signal line and the second signal line are covered by a first insulating layer among the plurality of insulating layers, and
wherein the first guide structure and the second guide structure are located at positions at which a portion of the first insulating layer is removed.

10. The display device of claim 7, wherein the rear part includes:
a first rear support layer, at least a portion of which includes a metallic material; and
a second rear support layer, at least a portion of which includes a nonmetallic material; and
wherein a first rear support layer includes the first structure contact area which the first guide structure is configured to contact while the display FPCB module is folded, and a second structure contact area which the second guide structure is configured to contact.

11. The display device of claim 7, wherein the rear part includes:
a first rear support layer, at least a portion of which includes a metallic material;
a second rear support layer, at least a portion of which includes a nonmetallic material; and
wherein the second rear support layer includes a third structure contact area which the first guide structure is configured to contact while the display FPCB module is folded, and a fourth structure contact area which the second guide structure is configured to contact.

12. A portable communication device comprising:
a display device; and
a housing, on which the display device is positioned, at least a portion of which includes a metallic material, and having a side wall configured as an antenna,
wherein the display device includes:
a display module including a panel part comprising a display panel, in which a plurality of pixels are disposed, and a rear part including a support layer supporting the panel part; and
a display flexible printed circuit board (FPCB) module including and FPCB connected to the display module, and including a folding area located within a specified distance at the side wall while being positioned on the housing, and
wherein the display FPCB module includes:
a guide structure comprising a guide disposed at a first position of a rear surface of the display FPCB module and configured to contact a portion of the rear part of the display module based on the display FPCB module being in a folded state;
a signal line connected to the guide structure; and
a connector connected to the signal line.

13. The portable communication device of claim 12, wherein the rear part includes:
a first rear support layer, at least a portion of which includes a metallic material;
a second rear support layer, at least a portion of which includes a nonmetallic material; and
a first structure contact area defined by a portion of the first rear support layer, and at least a portion of which is surrounded by the second rear support layer, and
wherein the first position corresponds to a position at which the guide structure contacts the first structure contact area, while the display FPCB is folded.

14. The portable communication device of claim 12, wherein the rear part includes:
a first rear support layer, at least a portion of which includes a metallic material;
a second rear support layer, at least a portion of which includes a nonmetallic material; and
a structure adhesion area disposed at a portion of the first rear support layer, and in which a conductive adhesion member comprising a conductive adhesive is disposed, and
wherein the first position corresponds to a position at which the guide structure is configured to contact the structure contact area, while the display FPCB is folded.

15. The portable communication device of claim 12, further comprising:
a detection circuit connected to the guide structure,
wherein the signal line includes:
a first signal line configured to supply electric power to the detection circuit; and
a second signal line configured to sense a change in a state of the detection circuit,
wherein the display FPCB module includes:
a plurality of metal pattern layers and a plurality of insulating layers,
wherein, among the plurality of metal pattern layers, a first metal pattern layer includes at least one ground terminal, the guide structure, the first signal line, and the second signal line,
wherein the first signal line and the second signal line are covered by, among the plurality of insulating layers, a first insulating layer, and
wherein the guide structure and the ground terminal are located at positions at which a portion of the first insulating layer is removed.

16. The portable communication device of claim 12, wherein the guide structure includes:
a first guide structure including a guide disposed at the first position; and
a second guide structure including a guide disposed at a second position different from the first position, and
wherein the signal line includes:
a first signal line connecting the connector and the first guide structure; and
a second signal line connecting the connector and the second guide structure.

17. The portable communication device of claim 16, wherein the rear part includes:
a first rear support layer, at least a portion of which includes a metallic material; and
a second rear support layer, at least a portion of which includes a nonmetallic material; and
wherein a first rear support layer includes the first structure contact area which the first guide structure is configured to contact while the display FPCB module is folded, and a second structure contact area which the second guide structure is configured to contact.

18. The portable communication device of claim 17, further comprising:
at least one processor, comprising processing circuitry, connected to the connector,
wherein at least one processor, individually and/or collectively, is configured to:
determine that the display FPCB module is in a normal state based on the first guide structure and the second guide structure being grounded, and output information corresponding to the normal state.

19. The portable communication device of claim 16, wherein the rear part includes:
a first rear support layer, at least a portion of which includes a metallic material; and
a second rear support layer, at least a portion of which includes a nonmetallic material;
wherein the second rear support layer includes a third structure contact area which the first guide structure is configured to contact while the display FPCB module is folded, and a fourth structure contact area which the second guide structure is configured to contact,
wherein the portable communication device further includes at least one processor, comprising processing circuitry, connected to the connector, and
wherein at least one processor, individually and/or collectively, is configured to:
determine that the display FPCB module is in a normal state based on the first guide structure and the second guide structure being floated, and output information corresponding to the normal state.

20. The portable communication device of claim 12, further comprising:
at least one processor, comprising processing circuitry, connected to the connector;
a housing, at least a portion of which is configured as an antenna, and in which the processor is disposed in an interior thereof; and
a tunable antenna electrically connected to a portion of the housing,
wherein at least one processor, individually and/or collectively, is configured to:
detect a change in a capacitance between the portion of the housing used as the antenna and the display FPCB module, calculate an antenna tuning value depending on the change in the capacitance, and apply the calculated antenna tuning value to the tunable antenna.
